(19) United States
(12) Patent Application Publication
(10) Pub. No.: US 2025/0047059 A1
(43) Pub. Date: Feb. 6, 2025

(54) SEMICONDUCTOR LIGHT EMITTING DEVICE

(71) Applicant: ROHM CO., LTD., Kyoto (JP)

(72) Inventor: Okimoto KONDO, Kyoto (JP)

(21) Appl. No.: 18/768,271

(22) Filed: Jul. 10, 2024

(30) Foreign Application Priority Data
Aug. 1, 2023 (JP) 2023-125794

(51) Int. Cl. H01S 5/0233; H01S 5/02234; H01S 5/023; H01S 5/0239

(52) U.S. Cl. CPC H01S 5/0233; H01S 5/02234; H01S 5/023; H01S 5/0239

(57) ABSTRACT

A semiconductor light emitting device includes: a substrate having a substrate front surface; a first front surface electrode, a second front surface electrode, and a third front surface electrode that are formed on the substrate front surface; an edge light emitting element that includes a first light emitting surface facing in a direction intersecting a thickness direction perpendicular to the substrate front surface and a second light emitting surface facing in a direction opposite to the first light emitting surface, and is electrically connected to the first front surface electrode; and a light receiving element that includes a second element front surface having a light receiving region and is electrically connected to the second front surface electrode and the third front surface electrode with the second element front surface facing the second light emitting surface.

### CROSS-REFERENCE TO RELATED APPLICATION

This application is based upon and claims the benefit of priority from Japanese Patent Application No. 2023-125794, filed on Aug. 1, 2023, the entire contents of which are incorporated herein by reference.

### TECHNICAL FIELD

The present disclosure relates to a semiconductor light emitting device.

### BACKGROUND

In the related art, a semiconductor light emitting device including a light emitting diode (LED) as a light source is known.

### BRIEF DESCRIPTION OF DRAWINGS

The accompanying drawings, which are incorporated in and constitute a part of the specification, illustrate embodiments of the present disclosure.

FIG. 1 is a schematic perspective view of a semiconductor light emitting device according to a first embodiment.

FIG. 2 is a schematic plan view of a state in which a seal is removed from the semiconductor light emitting device of FIG. 1.

FIG. 3 is a schematic cross-sectional view of the semiconductor light emitting device taken along line F3-F3 in FIG. 2.

FIG. 4 is a cross-sectional view of an edge light emitting element of the semiconductor light emitting device taken along line F4-F4 in FIG. 2.

FIG. 5 is a schematic side view of the edge light emitting element of FIG. 4.

FIG. 6 is a schematic cross-sectional view of a semiconductor light emitting device according to a second embodiment.

FIG. 7 is a schematic side view of the semiconductor light emitting device of FIG. 6.

FIG. 8 is a schematic cross-sectional view of a semiconductor light emitting device according to a third embodiment.

FIG. 9 is a schematic cross-sectional view of a semiconductor light emitting device according to a fourth embodiment.

FIG. 10 is a schematic cross-sectional view of a semiconductor light emitting device according to a fifth embodiment.

FIG. 11 is a schematic cross-sectional view of a semiconductor light emitting device according to a sixth embodiment.

FIG. 12 is a schematic cross-sectional view of a semiconductor light emitting device according to a seventh embodiment.

FIG. 13 is a schematic cross-sectional view of a semiconductor light emitting device according to an eighth embodiment.

FIG. 14 is a schematic cross-sectional view of a semiconductor light emitting device according to a modification.

FIG. 15 is a schematic cross-sectional view of a semiconductor light emitting device according to a modification.

FIG. 16 is a schematic plan view of a state in which a seal is removed from a semiconductor light emitting device according to a modification.

FIG. 17 is a schematic plan view of a state in which a seal is removed from a semiconductor light emitting device according to a modification.

FIG. 18 is a schematic plan view of a state in which a seal is removed from a semiconductor light emitting device according to a modification.

FIG. 19 is a schematic plan view of a semiconductor light emitting device according to a modification with a seal removed.

FIG. 20 is a schematic plan view of a state in which a seal is removed from a semiconductor light emitting device according to a modification.

FIG. 21 is a schematic plan view of a state in which a seal is removed from a semiconductor light emitting device according to a modification.

FIG. 22 is a schematic cross-sectional view of the semiconductor light emitting device taken along line F22-F22 in FIG. 21.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor light emitting device according to the present disclosure will be described with reference to the accompanying drawings. It should be noted that, for simplicity and clarity of explanation, the constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### First Embodiment

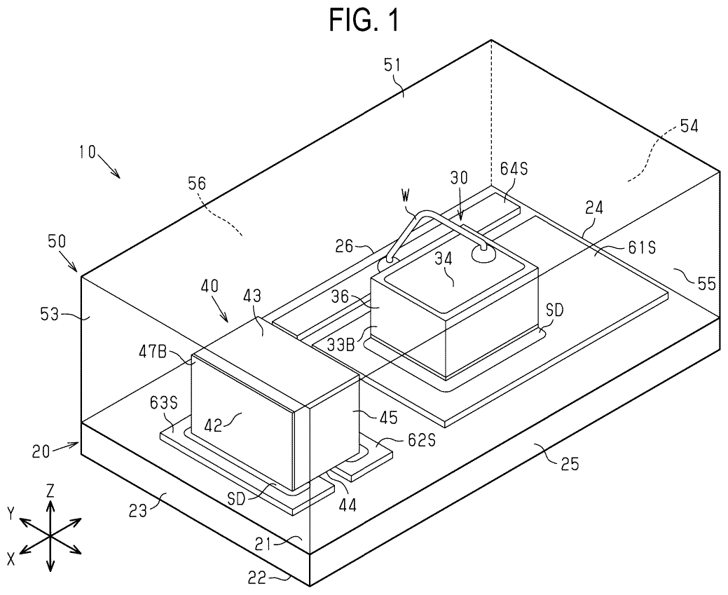

A semiconductor light emitting device 10 of a first embodiment will be described with reference to FIGS. 1 to 5.

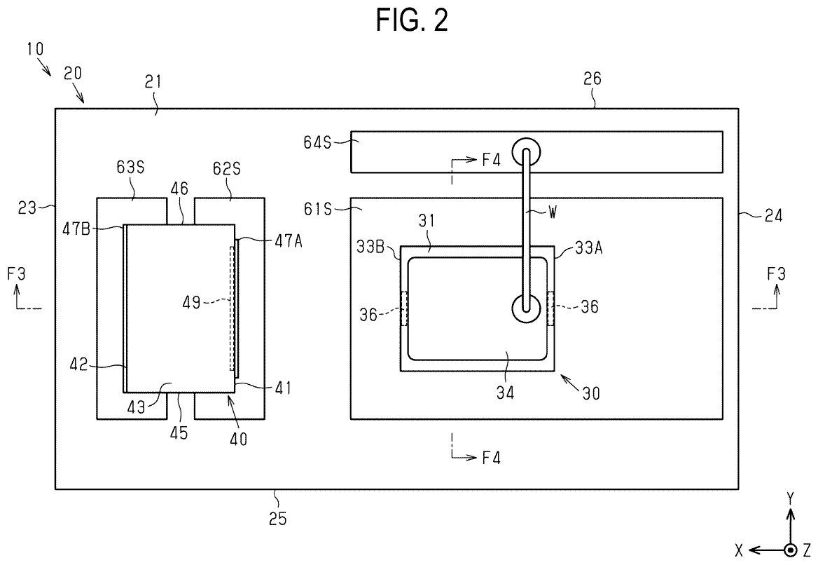

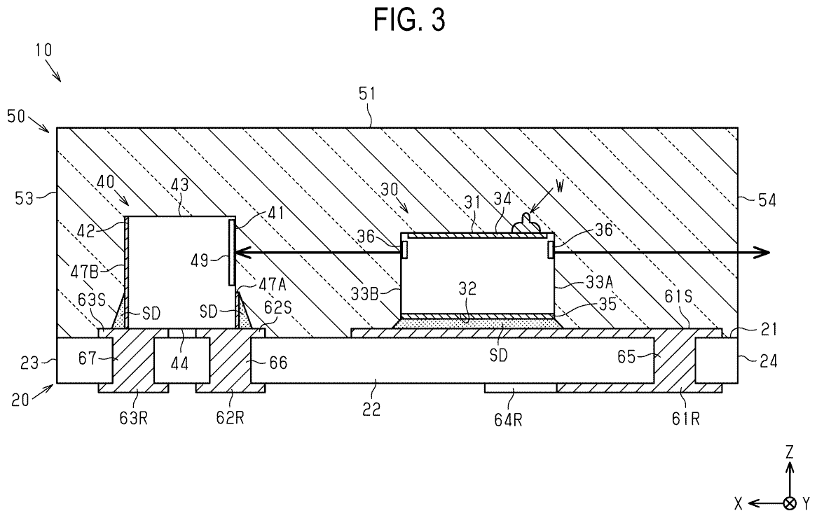

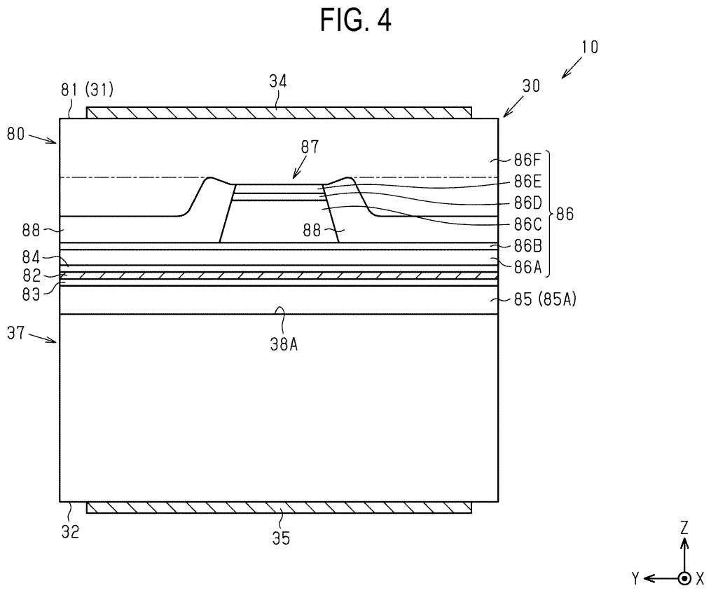

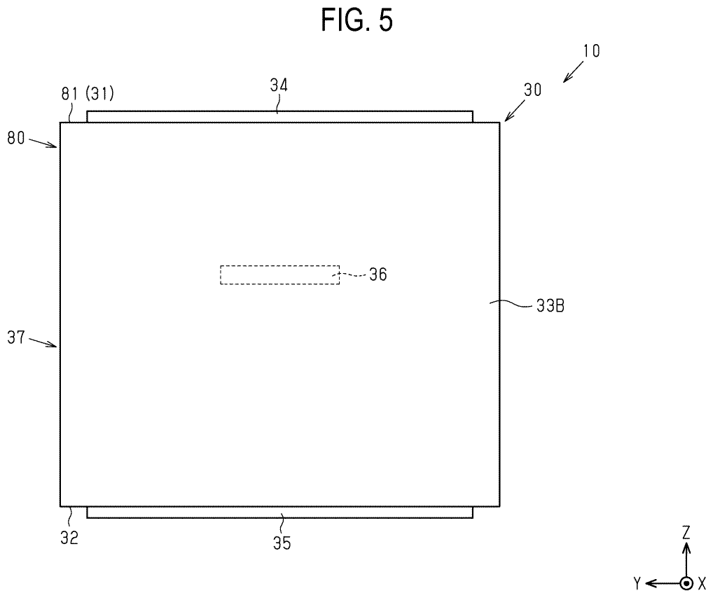

FIG. 1 shows a schematic perspective structure of the semiconductor light emitting device 10. FIG. 2 shows a schematic plan structure showing an interior of the semiconductor light emitting device 10 by omitting a seal 50, which will be described later, from the semiconductor light emitting device 10. FIG. 3 shows a schematic cross-sectional structure of the semiconductor light emitting device 10 taken along line F3-F3 in FIG. 2. FIG. 4 shows a cross-sectional view of the semiconductor light emitting device 10 taken along line F4-F4 in FIG. 2. FIG. 5 is a schematic side view of the semiconductor light emitting device 10 viewed from an X direction shown in FIG. 1.

The term “in a plan view” used in the present disclosure refers to viewing the semiconductor light emitting device 10 in a Z direction of the mutually orthogonal XYZ axes shown in FIG. 1.

As shown in FIG. 1, the semiconductor light emitting device 10 includes a substrate 20, an edge light emitting element 30 disposed on the substrate 20, a light receiving element 40 disposed on the substrate 20, and a seal 50 that seals at least a portion of the edge light emitting element 30 and at least a portion of the light receiving element 40. The seal 50 is an example of a cover that seals or accommodates at least a portion of the light receiving element 40 and at least a portion of the edge light emitting element 30.

The substrate 20 is a component that supports the edge light emitting element 30 and the light receiving element 40. The substrate 20 is formed in a rectangular flat plate shape with the Z direction being a thickness direction. In the following description, “in a plan view” is synonymous with “when viewed from the thickness direction of the substrate.”

As shown in FIG. 2, the substrate 20 is formed in a rectangular shape with the X direction being a longitudinal direction and a Y direction being a lateral direction in a plan view. As shown in FIG. 1, the substrate 20 has a substrate front surface 21, a substrate back surface 22 opposite to the substrate front surface 21 in the Z direction, and first to fourth substrate side surfaces 23 to 26 connecting the substrate front surface 21 and the substrate back surface 22 (see FIG. 2). The first substrate side surface 23 and the second substrate side surface 24 constitute both end surfaces of the substrate 20 in the X direction, and the third substrate side surface 25 and the fourth substrate side surface 26 constitute both end surfaces of the substrate 20 in the Y direction. The shape of the substrate 20 in a plan view can be arbitrarily changed.

The substrate 20 is made of, for example, an insulating material. The insulating material may be, for example, a material containing epoxy resin. As an example, the substrate 20 may be made of glass epoxy resin. Further, the insulating material may be, for example, a material containing ceramic. Examples of the ceramic-containing material may include aluminum nitride (AlN), alumina (Al₂O₃), and the like. When the substrate 20 is made of a material containing ceramic, heat dissipation performance of the substrate 20 is improved, so that a temperature of the semiconductor light emitting device 10 can be suppressed from becoming excessively high.

The edge light emitting element 30 and the light receiving element 40 are arranged to be spaced apart from each other in the X direction. In one example, the light receiving element 40 is arranged at a position overlapping the edge light emitting element 30 when viewed from the X direction. The light receiving element 40 is arranged to be closer to the first substrate side surface 23 than the edge light emitting element 30.

The edge light emitting element 30 is a laser diode that emits laser light in a predetermined wavelength band, and functions as a light source of the semiconductor light emitting device 10. As the edge light emitting element 30, for example, an edge emitting laser (EEL) is used. The laser light may be visible light, or may be laser light having a longer wavelength than the visible light such as ultraviolet light.

The edge light emitting element 30 is formed in a rectangular parallelepiped shape. In one example, as shown in FIG. 2, the edge light emitting element 30 is formed in a rectangular shape with the X direction being a longitudinal direction and the Y direction being a lateral direction in a plan view. The shape of the edge light emitting element 30 in a plan view can be arbitrarily changed. In one example, the shape of the edge light emitting element 30 in a plan view may be square.

As shown in FIGS. 1 and 3, the edge light emitting element 30 has a first element front surface 31 and a first element back surface 32 that face opposite to each other in the Z direction, and four element side surfaces connecting the first element front surface 31 and the first element back surface 32. Among the four element side surfaces, element side surfaces that constitute both end surfaces in the X direction constitute a first light emitting surface 33A and a second light emitting surface 33B. As shown in FIG. 3, both the first light emitting surface 33A and the second light emitting surface 33B are configured by flat surfaces orthogonal to the first element front surface 31 (the first element back surface 32). The first light emitting surface 33A and the second light emitting surface 33B face opposite to each other. The first light emitting surface 33A is configured to emit first laser light in the X direction, which is an example of a first direction (X direction) intersecting the Z direction in a plan view. A detailed configuration of a light emitting structure of the edge light emitting element 30 will be described later.

As shown in FIG. 1, the light receiving element 40 is formed in a rectangular flat plate shape having the X direction as a thickness direction. As shown in FIGS. 1 and 2, the light receiving element 40 has a second element front surface 41 and a second element back surface 42 facing opposite to each other in the thickness direction (X direction), and first to fourth element side surfaces 43 to 46 connecting the second element front surface 41 and the second element back surface 42. The first element side surface 43 and the second element side surface 44 constitute both end surfaces of the light receiving element 40 in the Z direction, and the third element side surface 45 and the fourth element side surface 46 constitute both end surfaces of the light receiving element 40 in the Y direction. The second element front surface 41 faces the same side as the second substrate side surface 24, and the second element back surface 42 faces the same side as the first substrate side surface 23. The first element side surface 43 faces the same side as the substrate front surface 21, and the second element side surface 44 faces the same side as the substrate back surface 22. The third element side surface 45 faces the same side as the third substrate side surface 25, and the fourth element side surface 46 faces the same side as the fourth substrate side surface 26.

The light receiving element 40 is, for example, a photo diode. The light receiving element 40 further includes a first light receiving electrode 47A and a second light receiving electrode 47B. As shown in FIGS. 2 and 3, the first light receiving electrode 47A is formed on the second element front surface 41. Further, the second light receiving electrode 47B is formed on the second element back surface 42. The first light receiving electrode 47A constitutes one of the anode and cathode of the photo diode, and the second light receiving electrode 47B constitutes the other of the anode and cathode of the photo diode. In the first embodiment, the first light receiving electrode 47A constitutes an anode, and the second light receiving electrode 47B constitutes a cathode.

The light receiving element 40 is formed on a portion of the substrate front surface 21 that is closer to the substrate side surface 23 than a center of the substrate front surface 21 in the X direction in a plan view. The light receiving element 40 includes a light receiving region 49. The light receiving region 49 is formed on the second element front surface 41. A formation range of the light receiving region 49 is defined, for example, by a p-type well region formed in an n-type semiconductor substrate provided in the light receiving element 40. That is, the light receiving element 40 is configured such that when the light receiving region 49 is irradiated with light, a current flows from the first light receiving electrode 47A of the light receiving element 40 to the second light receiving electrode 47B thereof.

The edge light emitting element 30 includes a first light emitting electrode 34 formed on the first element front surface 31, and a second light emitting electrode 35 formed on the first element back surface 32. As shown in FIG. 2, the first light emitting electrode 34 is formed substantially at a center of the first element front surface 31 in the Y direction in a plan view. A shape of the first light emitting electrode 34 in a plan view is a rectangular shape having the X direction as a longitudinal direction and the Y direction as a lateral direction. As shown in FIG. 3, the second light emitting electrode 35 is formed to have the same length in the X direction as the first element back surface 32, for example. Further, as shown in FIGS. 4 and 5, in one example, a dimension of the second light emitting electrode 35 in the Y direction is smaller than a dimension of the first element back surface 32 in the Y direction. In one example, the first light emitting electrode 34 forms an anode and the second light emitting electrode 35 forms a cathode.

The edge light emitting element 30 is formed into a rectangular flat plate shape having the Z direction as a thickness direction. The shape of the edge light emitting element 30 in a plan view is a rectangular shape having the X direction as a longitudinal direction and the Y direction as a lateral direction. In the example shown in FIG. 2, the first light emitting electrode 34 is formed to be smaller than the edge light emitting element 30 in a plan view. The first light emitting electrode 34 may have a stacked structure of a plurality of electrode films.

As shown in FIG. 1, the seal 50 is provided on the substrate 20. The seal 50 is made of a material through which the first laser light and second laser light of the edge light emitting element 30 can pass. The seal 50 is made of a material containing at least one of, for example, silicone resin, epoxy resin, or acrylic resin. In one example, the seal 50 is made of silicone resin. In the first embodiment, the seal 50 seals the entire light receiving element 40 and the entire edge light emitting element 30.

The seal 50 is formed into a substantially rectangular flat plate shape having the Z direction as a thickness direction. The seal 50 has a sealing front surface 51 facing the same side as the substrate front surface 21 and first to fourth sealing side surfaces 53 to 56 that intersect the sealing front surface 51.

The sealing front surface 51 is a flat surface orthogonal to the thickness direction (Z direction) of the substrate 20. Therefore, “in a plan view” can be paraphrased as “when viewed from a direction perpendicular to the sealing front surface 51.” The first to fourth sealing side surfaces 53 to 56 are orthogonal to the sealing front surface 51, for example. The first sealing side surface 53 and the second sealing side surface 54 constitute both end surfaces of the seal 50 in the X direction, and the third sealing side surface 55 and the fourth sealing side surface 56 constitute both end surfaces of the seal 50 in the Y direction. The first sealing side surface 53 faces the same side as the first substrate side surface 23, and the second sealing side surface 54 faces the same side as the second substrate side surface 24. The third sealing side surface 55 faces the same side as the third substrate side surface 25, and the fourth sealing side surface 56 faces the same side as the fourth substrate side surface 26. In one example, the first sealing side surface 53 and the first substrate side surface 23 are formed to be flush with each other, and the second sealing side surface 54 and the second substrate side surface 24 are formed to be flush with each other. The third sealing side surface 55 and the third substrate side surface 25 are formed to be flush with each other, and the fourth sealing side surface 56 and the fourth substrate side surface 26 are formed to be flush with each other.

The first light emitting surface 33A is configured to emit the first laser light toward the second sealing side surface 54 of the seal 50. The first laser light from the edge light emitting element 30 passes through the second sealing side surface 54 and is emitted to the outside of the semiconductor light emitting device 10. The second light emitting surface 33B is configured to emit the second laser light in a direction opposite to the emission direction of the first laser light in a plan view. That is, the second light emitting surface 33B is configured to emit the second laser light toward a side opposite to the second sealing side surface 54 of the seal 50, in other words, toward a side where the first sealing side surface 53 is disposed.

### [Electrical Connection Configuration of Semiconductor Light Emitting Device]

As shown in FIGS. 2 and 3, the semiconductor light emitting device 10 includes a first front surface electrode 61S, a second front surface electrode 62S, a third front surface electrode 63S, and a fourth front surface electrode 64S, which are provided on the substrate front surface 21, a first back surface electrode 61R, a second back surface electrode 62R, a third back surface electrode 63R, and a fourth back surface electrode 64R, which are provided on the substrate back surface 22, and a first via 65, a second via 66, a third via 67, and a fourth via (not shown), which are provided inside the substrate 20. The first to fourth front surface electrodes 61S to 64S, the first to fourth back surface electrodes 61R to 64R, the first to third vias 65 to 67, and the fourth via are made of a material containing one or more selected as appropriate from, for example, Ti (titanium), TiN (titanium nitride), Au (gold), Ag (silver), Cu (copper), Al (aluminum), and W (tungsten).

As shown in FIG. 2, the first front surface electrode 61S is disposed to be closer to the second substrate side surface 24 than the center of the substrate front surface 21 in the X direction in a plan view. In the example of FIG. 2, the first front surface electrode 61S is formed in a rectangular shape having the X direction as a longitudinal direction and the Y direction as a lateral direction in a plan view. The arrangement position and shape of the first front surface electrode 61S with respect to the substrate front surface 21 can be arbitrarily changed.

The second front surface electrode 62S and the third front surface electrode 63S are disposed to be spaced apart from the first front surface electrode 61S. The second front surface electrode 62S and the third front surface electrode 63S are disposed to be closer to the first substrate side surface 23 than the first front surface electrode 61S in the X direction. The third front surface electrode 63S and the second front surface electrode 62S are disposed to be spaced apart from each other. The third front surface electrode 63S is disposed to be closer to the first substrate side surface 23 than the second front surface electrode 62S in the X direction. In one example, the third front surface electrode 63S is disposed at a position adjacent to the first substrate side surface 23 in the X direction in a plan view. That is, in the X direction, the second front surface electrode 62S is disposed between the first front surface electrode 61S and the third front surface electrode 63S. In one example, the second front surface electrode 62S is disposed to be closer to the third front surface electrode 63S than the first front surface electrode 61S.

The second front surface electrode 62S is formed in a rectangular shape having the Y direction as a longitudinal direction and the X direction as a lateral direction in a plan view. The second front surface electrode 62S is disposed to be spaced apart from the first front surface electrode 61S in the X direction. The third front surface electrode 63S is formed in a rectangular shape having the Y direction as a longitudinal direction and the X direction as a lateral direction in a plan view. In one example, the third front surface electrode 63S has the same size and shape as the second front surface electrode 62S. The shapes and sizes of the second front surface electrode 62S and the third front surface electrode 63S in a plan view can be arbitrarily changed.

The fourth front surface electrode 64S is disposed to be closer to the second substrate side surface 24 than the second front surface electrode 62S and the third front surface electrode 63S in the X direction. The fourth front surface electrode 64S is disposed at a position overlapping the first front surface electrode 61S when viewed from the Y direction. The fourth front surface electrode 64S is disposed to be closer to the third substrate side surface 25 than the first front surface electrode 61S. The fourth front surface electrode 64S is formed in a rectangular shape having the X direction as a longitudinal direction and the Y direction as a lateral direction in a plan view. The arrangement mode of the first to fourth front surface electrodes 61S to 64S can be arbitrarily changed.

The edge light emitting element 30 is disposed on the first front surface electrode 61S so that the second light emitting electrode 35 faces the first front surface electrode 61S. More specifically, as shown in FIG. 3, the edge light emitting element 30 is bonded to the first front surface electrode 61S by a conductive bonding material SD. Thus, the second light emitting electrode 35 is electrically connected to the first front surface electrode 61S. As described above, the edge light emitting element 30 is electrically connected to the first front surface electrode 61S. As the conductive bonding material SD, for example, solder paste, silver paste, gold paste, copper paste, and the like may be used.

As shown in FIG. 2, a wire W is connected to the first light emitting electrode 34 of the edge light emitting element 30. The wire W is connected to the fourth front surface electrode 64S. Thus, the first light emitting electrode 34 of the edge light emitting element 30, the first front surface electrode 61S, and the fourth front surface electrode 64S are electrically connected to one another via the wire W. In the example shown in FIG. 2, the wire W is formed to extend in the Y direction in a plan view. In the first embodiment, the wire W is sealed by the seal 50. The wire W is a bonding wire formed by, for example, a wire bonding device, and is made of, for example, a conductive material such as Au, Al, Cu, and the like.

The light receiving element 40 is disposed on the second front surface electrode 62S and the third front surface electrode 63S, so that the first light receiving electrode 47A faces the second front surface electrode 62S in the Z direction and the second light receiving electrode 47B faces the third front surface electrode 63S in the Z direction. More specifically, as shown in FIG. 3, the first light receiving electrode 47A is bonded to the second front surface electrode 62S by the conductive bonding material SD, and the second light receiving electrode 47B is bonded to the third front surface electrode 63S by the conductive bonding material SD. Thus, the first light receiving electrode 47A is electrically connected to the second front surface electrode 62S, and the second light receiving electrode 47B is electrically connected to the third front surface electrode 63S.

As shown in FIG. 3, the first back surface electrode 61R is formed at an end portion, which is closer to the second substrate side surface 24, of both end portions of the substrate back surface 22 in the X direction. In a plan view, the first back surface electrode 61R includes a portion that overlaps the first front surface electrode 61S.

The second back surface electrode 62R is disposed on the substrate back surface 22 to be spaced apart from the first back surface electrode 61R in the X direction. In a plan view, the second back surface electrode 62R includes a portion that overlaps the second front surface electrode 62S.

The third back surface electrode 63R is disposed to be spaced apart from both the first back surface electrode 61R and the second back surface electrode 62R in the X direction in a plan view. In one example, the third back surface electrode 63R is disposed at a position adjacent to the first substrate side surface 23 in the X direction in a plan view. In a plan view, the third back surface electrode 63R includes a portion that overlaps the third front surface electrode 63S.

The fourth back surface electrode 64R is disposed to be spaced apart from the first to third back surface electrodes 61R to 63R in a plan view. In a plan view, the fourth back surface electrode 64R includes a portion that overlaps the fourth front surface electrode 64S (see FIG. 2).

The first via 65 electrically connects the first front surface electrode 61S and the first back surface electrode 61R. The second via 66 electrically connects the second front surface electrode 62S and the second back surface electrode 62R. The third via 67 electrically connects the third front surface electrode 63S and the third back surface electrode 63R. The fourth via electrically connects the fourth front surface electrode 64S and the fourth back surface electrode 64R. Each of the first via 65, the second via 66, the third via 67, and the fourth via penetrates the substrate 20 in the Z direction. Each of the first via 65, the second via 66, the third via 67, and the fourth via may be provided in plural.

The first back surface electrode 61R is electrically connected to the second light emitting electrode 35 of the edge light emitting element 30 via the first front surface electrode 61S and the first via 65. The second back surface electrode 62R is electrically connected to the first light receiving electrode 47A of the light receiving element 40 via the second front surface electrode 62S and the second via 66. The third back surface electrode 63R is electrically connected to the second light receiving electrode 47B of the light receiving element 40 via the third front surface electrode 63S and the third via 67. The fourth back surface electrode 64R is electrically connected to the first light emitting electrode 34 of the edge light emitting element 30 via the fourth front surface electrode 64S, the fourth via, and the wire W. As described above, the semiconductor light emitting device 10 is configured as a surface-mounted package structure.

The semiconductor light emitting device 10 can use so-called APC (Auto Power Control) driving to control a current supplied to the edge light emitting element 30 so that optical outputs of the first laser light and the second laser light of the edge light emitting element 30 are kept constant. More specifically, a control device, which is provided outside the semiconductor light emitting device 10 and controls the current supplied to the edge light emitting element 30, receives a signal corresponding to the second laser light of the edge light emitting element 30 which is received by the light receiving element 40. In one example, the signal of the light receiving element 40 is output to the control device via the third back surface electrode 63R. The control device receives the signal of the light receiving element 40 by being electrically connected to the third back surface electrode 63R. In addition, the control device controls the current supplied to the edge light emitting element 30 according to a difference between the received signal and an output setting value that is a preset optical output. In one example, the control device controls the current supplied to the edge light emitting element 30 so that a level of the received signal matches the output setting value.

### [Internal Configuration of Edge Light Emitting Element]

An internal configuration of the edge light emitting element 30 will be described with reference to FIGS. 4 and 5. FIG. 4 shows a cross-sectional structure of the semiconductor light emitting device 10 taken along the line F4-F4 in FIG. 2, and shows the internal configuration of the edge light emitting element 30. FIG. 5 is a schematic side view of the semiconductor light emitting device 10 of FIG. 2 viewed from the X direction.

Further, in the examples shown in FIGS. 3 and 4, the second light emitting electrode 35 has the same length as the edge light emitting element 30 in the X direction and is formed to be smaller than the edge light emitting element 30 in the Y direction.

As shown in FIG. 4, the edge light emitting element 30 includes a semiconductor substrate 37 and a semiconductor layer 80 provided on the semiconductor substrate 37. The semiconductor substrate 37 is formed in a rectangular flat plate shape having the Z direction as a thickness direction. The semiconductor substrate 37 is formed in a rectangular shape having the X direction as a longitudinal direction and the Y direction as a lateral direction in a plan view (see FIG. 2).

In FIG. 4, in order to show respective components of the semiconductor layer 80, an overall thickness of the semiconductor layer 80 is shown to be as thick as a thickness of the semiconductor substrate 37, but actually, the thickness of the semiconductor layer 80 is smaller than the thickness of the semiconductor substrate 37.

The semiconductor substrate 37 is formed by, for example, an n-type semiconductor substrate (n-GaAs substrate) containing GaAs (gallium arsenide). The semiconductor substrate 37 contains at least one pentavalent element as n-type impurities. The semiconductor layer 80 is formed by, for example, an n-type semiconductor substrate (n-GaAs substrate) containing GaAs (gallium arsenide).

The semiconductor substrate 37 has a substrate front surface 38A and a substrate back surface 38B, and the semiconductor layer 80 is formed on the substrate front surface 38A. The semiconductor layer 80 has a front surface 81 that constitutes the first element front surface 31. The semiconductor layer 80 is epitaxially grown on the semiconductor substrate 37. The semiconductor layer 80 has a stacked structure in which a plurality of semiconductor layers is stacked in the Z direction.

As shown in FIG. 4, the semiconductor layer 80 includes, as the plurality of semiconductor layers, an active layer 82, an n-side guide layer 83, a p-side guide layer 84, an n-type semiconductor layer 85, and a p-type semiconductor layer 86.

The n-side guide layer 83 is disposed between the n-type semiconductor layer 85 and the active layer 82 and the p-side guide layer 84 is disposed between the active layer 82 and the p-type semiconductor layer 86, thereby forming a double hetero-junction. Electrons are injected into the active layer 82 from the n-type semiconductor layer 85 via the n-side guide layer 83, and holes are injected into the active layer 82 from the p-type semiconductor layer 86 via the p-side guide layer 84. The electrons and the holes are recombined in the active layer 82, and thus laser light is generated in the active layer 82.

The laser light generated by the active layer 82 is emitted from the first light emitting surface 33A and the second light emitting surface 33B. It can be said that the edge light emitting element 30 is configured such that the laser light generated by the active layer 82 is emitted from the first light emitting surface 33A and the second light emitting surface 33B. It can be said that the first light emitting surface 33A and the second light emitting surface 33B include an emission region 36 from which the laser light is emitted. Since the emission region 36 is formed correspondingly to the semiconductor layer 80, as shown in FIG. 5, the emission region 36 is disposed to be closer to the first element front surface 31 than a center of the edge light emitting element 30 in the Z direction. A dimension of the emission region 36 in the Y direction is smaller than a dimension of the second light emitting surface 33B in the Y direction.

The n-type semiconductor layer 85 includes an n-type cladding layer 85A formed on the semiconductor substrate 37. The n-type cladding layer 85A is disposed on a side of the semiconductor substrate 37 with respect to the active layer 82. The n-type cladding layer 85A is made of a material containing, for example, AlGaAs (aluminum gallium arsenide). The n-type cladding layer 85A has a thickness of, for example, 20,000 angstroms or more and 35,000 angstroms or less. The n-type cladding layer 85A is formed by, for example, an AlxGa₍₁₋ₓ₎As (0≤x≤1) layer.

The p-type semiconductor layer 86 includes a first p-type cladding layer 86A, a first p-type etching stop layer 86B, a second p-type cladding layer 86C, a second p-type etching stop layer 86D, a p-type cap layer 86E, and a p-type contact layer 86F, which are stacked on the p-side guide layer 84. Here, both the first p-type cladding layer 86A and the second p-type cladding layer 86C are examples of a “p-type cladding layer.”

The first p-type cladding layer 86A and the second p-type cladding layer 86C are disposed on the opposite side of the n-type cladding layer 85A with respect to the active layer 82. Each of the first p-type cladding layer 86A and the second p-type cladding layer 86C is made of a material containing, for example, AlGaAs. The first p-type cladding layer 86A has a thickness of, for example, 1,000 angstroms or more and 2,000 angstroms or less. The second p-type cladding layer 86C has a thickness of, for example, 8,000 angstroms or more and 12,000 angstroms or less. That is, the thickness of the second p-type cladding layer 86C is larger than the thickness of the first p-type cladding layer 86A. Each of the first p-type cladding layer 86A and the second p-type cladding layer 86C is formed by, for example, an AlxGa₍₁₋ₓ₎As (0≤x≤1) layer.

Each of the first p-type etching stop layer 86B and the second p-type etching stop layer 86D is made of a material containing, for example, InGaP (indium gallium phosphide). A thickness of each of the first p-type etching stop layer 86B and the second p-type etching stop layer 86D is smaller than the thickness of each of the first p-type cladding layer 86A and the second p-type cladding layer 86C. The first p-type etching stop layer 86B has a thickness of, for example, 50 angstroms or more and 300 angstroms or less. The second p-type etching stop layer 86D has a thickness of, for example, 50 angstroms or more and 300 angstroms or less.

The p-type cap layer 86E is made of a material containing, for example, GaAs. A thickness of the p-type cap layer 86E is, for example, larger than the thickness of each of the first p-type etching stop layer 86B and the second p-type etching stop layer 86D and smaller than the thickness of each of the first p-type cladding layer 86A and the second p-type cladding layer 86C. The p-type cap layer 86E has a thickness of, for example, 1,000 angstroms or more and 3,000 angstroms or less.

The p-type contact layer 86F is a low-resistance layer for forming an ohmic contact with the first light emitting electrode 34. The p-type contact layer 86F is formed as a p-type semiconductor layer in which, for example, Be (beryllium) as a p-type dopant is implanted into GaAs. A thickness of the p-type contact layer 86F is larger than the thickness of each of the first p-type cladding layer 86A, the first p-type etching stop layer 86B, the second p-type cladding layer 86C, the second p-type etching stop layer 86D, and the p-type cap layer 86E. The p-type contact layer 86F has a thickness of, for example, 30,000 angstroms or more and 60,000 angstroms or less.

The n-type cladding layer 85A, the first p-type cladding layer 86A, and the second p-type cladding layer 86C are configured to make an effect of confining carriers (electrons and holes) in the active layer 82 and an effect of confining the laser light from the active layer 82 between the n-type cladding layer 85A and the first p-type cladding layer 86A and between the n-type cladding layer 85A and the second p-type cladding layer 86C. The n-type cladding layer 85A is formed as an n-type semiconductor layer in which, for example, Si (silicon) as an n-type dopant is implanted into AlGaAs. Each of the first p-type cladding layer 86A and the second p-type cladding layer 86C is formed as a p-type semiconductor layer in which, for example, Be as a p-type dopant is implanted into AlGaAs.

The n-type cladding layer 85A has a larger band gap than the n-side guide layer 83. The first p-type cladding layer 86A and the second p-type cladding layer 86C have a larger band gap than the p-side guide layer 84. This increases the effect of confining carriers in the active layer 82 and the effect of confining the laser light from the active layer 82 between the n-type cladding layer 85A and the first p-type cladding layer 86A and between the n-type cladding layer 85A and the second p-type cladding layer 86C. Thus, the edge light emitting element 30 can be implemented with high efficiency.

Each of the n-side guide layer 83 and the p-side guide layer 84 is made of a material containing AlGaAs. Each of the n-side guide layer 83 and the p-side guide layer 84 has a thickness of, for example, 200 angstroms or more and 500 angstroms or less. The n-side guide layer 83 is stacked on the n-type semiconductor layer 85. The p-side guide layer 84 is stacked on the active layer 82. Each of the n-side guide layer 83 and the p-side guide layer 84 is formed by, for example, an AlxGa₍₁₋ₓ₎As (0≤x≤1) layer.

The active layer 82 has a multiple-quantum well (MQW) structure. The active layer 82 is a layer for generating laser light by recombination of electrons and holes and amplifying the generated laser light. The active layer 82 is formed by alternately and repeatedly stacking a quantum well layer, which is formed of an undoped GaAsP layer, and a barrier layer, which is formed of an undoped InAlGaAs layer, over a plurality of periods.

A ridge portion 87 is formed by removing a portion of each of the second p-type cladding layer 86C, the second p-type etching stop layer 86D, and the p-type cap layer 86E in the p-type semiconductor layer 86. In one example, the ridge portion 87 having a substantially trapezoidal shape (mesa shape) in the cross section shown in FIG. 4 is formed by removing portions of the second p-type cladding layer 86C, the second p-type etching stop layer 86D, and the p-type cap layer 86E by etching. The emission region 36 (see FIG. 5) is formed to be closer to the n-type semiconductor layer 85 than the ridge portion 87 and at the same position as the ridge portion 87 in the Y direction. A dimension of the emission region 36 in the Y direction is, for example, substantially equal to a maximum dimension of the ridge portion 87 in the Y direction.

A current confinement layer 88 is formed on a side surface of the ridge portion 87. In one example, a side surface of the p-type cap layer 86E, a side surface of the second p-type etching stop layer 86D, a side surface of the second p-type cladding layer 86C, and an exposed surface of the first p-type etching stop layer 86B are covered by the current confinement layer 88. The current confinement layer 88 and the exposed surface of the p-type cap layer 86E are covered with the p-type contact layer 86F.

In the edge light emitting element 30, a Fabry-Perot resonator having the first light emitting surface 33A and the second light emitting surface 33B (both see FIG. 2) as resonator end surfaces is formed by the n-side guide layer 83, the active layer 82, and the p-side guide layer 84. More specifically, the laser light generated in the active layer 82 is amplified by stimulated emission while reciprocating between the first light emitting surface 33A and the second light emitting surface 33B. Further, a portion of the amplified laser light is emitted as laser light from the first light emitting surface 33A and the second light emitting surface 33B. Here, in the present disclosure, an edge film (not shown) is formed on each of the first light emitting surface 33A and the second light emitting surface 33B. This edge film may include a reflective film having insulating properties. Further, the edge film may include an anti-reflection coating (AR coat) having insulating properties. A reflectance of the edge film including the reflective film may be adjusted. In one example, reflective films may be formed so that the first light emitting surface 33A mainly emits laser light and the second light emitting surface 33B hardly emits laser light. That is, the edge film of the second light emitting surface 33B may be adjusted to have a higher reflectance than the edge film of the first light emitting surface 33A. With this configuration, an intensity of the second laser light emitted from the second light emitting surface 33B becomes lower than an intensity of the first laser light emitted from the first light emitting surface 33A. For example, it can be said that the second laser light is laser light that leaks from the second light emitting surface 33B when the edge light emitting element 30 emits the first laser light.

### [Arrangement Mode of Light Receiving Element]

The light receiving element 40 is disposed on the second front surface electrode 62S and the third front surface electrode 63S with the light receiving region 49 and the first light receiving electrode 47A lined up in the Z direction. The first light receiving electrode 47A is disposed to be closer to the second front surface electrode 62S than the light receiving region 49. The first light receiving electrode 47A is adjacent to the second front surface electrode 62S in the Z direction. In other words, the light receiving region 49 is disposed at a position spaced apart from the second front surface electrode 62S in the Z direction. Therefore, the light receiving region 49 is formed such that its center in the Z direction is closer to an upper side (the sealing front surface 51) than a center of the second element front surface 41 in the Z direction.

The light receiving element 40 and the edge light emitting element 30 are arranged to be spaced apart from each other in the X direction. When viewed from the X direction, the light receiving element 40 is disposed at a position that overlaps the edge light emitting element 30. The light receiving element 40 is disposed on the opposite side of the first light emitting surface 33A with respect to the second light emitting surface 33B of the edge light emitting element 30. The second element front surface 41 of the light receiving element 40 is located on the opposite side of the first light emitting surface 33A with respect to the second light emitting surface 33B of the edge light emitting element 30 in the X direction. The light receiving element 40 is disposed on the second front surface electrode 62S and the third front surface electrode 63S with the second element front surface 41 facing the second light emitting surface 33B. Further, the light receiving region 49 formed on the second element front surface 41 faces the second light emitting surface 33B in the X direction.

In one example, a dimension of the light receiving element 40 in the Y direction is larger than a dimension of the edge light emitting element 30 in the Y direction. That is, a dimension of the second element front surface 41 in the Y direction is larger than a dimension of the second light emitting surface 33B in the Y direction. Further, in one example, a dimension of the light receiving element 40 in the Z direction is larger than a dimension of the edge light emitting element 30 in the Z direction. That is, a dimension of the second element front surface 41 in the Z direction is larger than a dimension of the second light emitting surface 33B in the Z direction. Therefore, the first element side surface 43 of the light receiving element 40 is located to be closer to the sealing front surface 51 of the seal 50 than the first element front surface 31 of the edge light emitting element 30.

The second element front surface 41 is disposed at a position facing the second laser light from the second light emitting surface 33B. Therefore, a position of the light receiving region 49 of the light receiving element 40 is set such that the second laser light from the second light emitting surface 33B of the edge light emitting element 30 directly enters the light receiving region 49. More specifically, the light receiving region 49 faces the emission region 36 in the second light emitting surface 33B of the edge light emitting element 30 in the X direction. A center of the light receiving region 49 faces the emission region 36 in the X direction. In the first embodiment, the center of the light receiving region 49 faces a center of the emission region 36. Here, the center of the light receiving region 49 means at least a center of the light receiving region 49 in the Z direction. In the first embodiment, a center of the light receiving region 49 in the Y direction faces the emission region 36 in the X direction. As described above, since the first element side surface 43 of the light receiving element 40 is located to be closer to the sealing front surface 51 than the first element front surface 31 of the edge light emitting element 30, it is easy for the light receiving region 49 of the light receiving element 40 to face the emission region 36 of the second light emitting surface 33B, which is formed to be closer to the first element front surface 31, in the X direction.

An area of the light receiving region 49 is larger than an area of the emission region 36 when viewed from the X direction. In one example, a size of the light receiving region 49 in the Z direction is larger than a size of the emission region 36 in the Z direction. In one example, a size of the light receiving region 49 in the Y direction is larger than a size of the emission region 36 in the Y direction. Therefore, even when the second laser light emitted from the emission region 36 in the X direction spreads toward the light receiving region 49, it is easy for the light receiving region 49 to directly receive the second laser light.

Since the dimension of the light receiving element 40 in the Z direction is larger than the dimension of the edge light emitting element 30 in the Z direction, the light receiving region 49 includes a region that protrudes above the first element front surface 31 of the edge light emitting element 30 (closer to the sealing front surface 51) when viewed from the X direction.

### [Operation]

An operation of the semiconductor light emitting device 10 of the first embodiment will be described.

In an edge light emitting element such as an EEL, outputs of a first laser light and a second laser light change according to a temperature of the edge light emitting element. More specifically, the outputs of the first laser light and the second laser light of the edge light emitting element decrease as the temperature of the edge light emitting element increases. On the other hand, in the semiconductor light emitting device 10, at least the output of the first laser light is required to be constant regardless of temperature. Further, the output of the first laser light emitted from the first light emitting surface 33A of the edge light emitting element 30 and the output of the second laser light emitted from the second light emitting surface 33B have a correlation. Based on this correlation, the output of the first laser light can be recognized from the output of the second laser light.

Therefore, in the semiconductor light emitting device 10, after recognizing the output of the first laser light emitted from the edge light emitting element 30 by receiving the second laser light emitted from the second light emitting surface 33B of the edge light emitting element 30 by the light receiving element 40, so-called APC driving is performed to control the output of the first laser light from the edge light emitting element 30 so that the output of the first laser light becomes a predetermined output. That is, an amount of current supplied to the edge light emitting element 30 is controlled according to a difference between the output of the second laser light received by the light receiving element 40 and the output setting value. Thus, the output of the first laser light of the edge light emitting element 30 becomes the predetermined output of the first laser light.

As a configuration of a semiconductor light emitting device in which APC driving is performed, for example, a configuration (hereinafter referred to as a “comparative configuration”) can be considered in which a light receiving element is mounted on a substrate with a surface having a light receiving region parallel to a front surface of the substrate and an edge light emitting element is mounted on the front surface of the substrate. That is, the comparative configuration is a configuration in which both the light receiving element and the edge light emitting element are disposed on the same plane. However, in the comparative configuration, it is difficult for the light receiving element to directly receive laser light emitted from the edge light emitting element in a direction parallel to the front surface of the substrate.

Accordingly, the light receiving element 40 is disposed such that a surface (the second element front surface 41) having the light receiving region 49 is perpendicular to a surface (the substrate front surface 21) to which the light receiving element 40 is attached. Further, the light receiving element 40 is disposed such that the second element front surface 41 having the light receiving region 49 faces the second light emitting surface 33B of the edge light emitting element 30. As a result, in the semiconductor light emitting device 10, the light receiving element 40 can directly receive the second laser light from the second light emitting surface 33B of the edge light emitting element 30. Therefore, even when the edge light emitting element 30 and the light receiving element 40 are provided on the same plane, since the second laser light from the edge light emitting element 30 is directly incident on the light receiving region 49 of the light receiving element 40, a current supplied to the edge light emitting element 30 can be controlled by APC driving based on an amount of light received by the light receiving region 49.

### [Effects]

According to the semiconductor light emitting device 10 of the first embodiment, the following effects can be obtained.

(1-1) The semiconductor light emitting device 10 includes: the first front surface electrode 61S, the second front surface electrode 62S, and the third front surface electrode 63S, which are formed on the substrate front surface 21; the edge light emitting element 30 that has the first light emitting surface 33A facing a direction intersecting the thickness direction perpendicular to the substrate front surface 21, and the second light emitting surface 33B facing a direction opposite to the first light emitting surface 33A, and is electrically connected to the first front surface electrode 61S; and the light receiving element 40 that has the second element front surface 41 including the light receiving region 49 and is electrically connected to the second front surface electrode 62S and the third front surface electrode 63S with the second element front surface 41 facing the second light emitting surface 33B.

With this configuration, the edge light emitting element 30 and the light receiving element 40 are disposed on the substrate 20, and the second element front surface 41 is disposed at a position where the second laser light from the second light emitting surface 33B of the edge light emitting element 30 is directly received. Thus, the light receiving element 40 can directly receive the second laser light from the edge light emitting element 30. Therefore, when the semiconductor light emitting device 10 is controlled by APC driving, the output of the first laser light from the first light emitting surface 33A of the edge light emitting element 30 can be controlled to be a preset value based on the amount of light received by the second laser light that is directly incident on the light receiving element 40.

(1-2) The semiconductor light emitting device 10 further includes the seal 50 that seals at least a portion of the edge light emitting element 30 and the light receiving element 40.

With this configuration, since the edge light emitting element 30 and the light receiving element 40 are sealed by the seal 50, it is possible to suppress foreign substances such as moisture and dust from adhering to the edge light emitting element 30 and the light receiving element 40. Further, for example, as compared to a configuration in which the edge light emitting element 30 and the light receiving element 40 are sealed by, instead of the seal 50, a transparent side wall that is provided on the substrate 20 and surrounds the edge light emitting element 30 and the light receiving element 40, and a transparent cap that covers an opening of the side wall, it is possible to simplify a manufacturing process and reduce manufacturing costs.

(1-3) The edge light emitting element 30 includes the first element front surface 31 facing the same side as the substrate front surface 21, the first element back surface 32 facing the opposite side to the first element front surface 31, the first light emitting electrode 34 formed on the first element front surface 31, and the second light emitting electrode 35 formed on the first element back surface 32. The second light emitting electrode 35 of the edge light emitting element 30 is electrically connected to the first front surface electrode 61S.

With this configuration, in a state where the edge light emitting element 30 is disposed with the second light emitting surface 33B facing the second element front surface 41 of the light receiving element 40, the second light emitting electrode 35 faces the first front surface electrode 61S in the Z the direction. Therefore, as compared to a configuration in which the second light emitting electrode 35 and the first front surface electrode 61S are connected by a wire, it is possible to shorten a length of a conductive path between the second light emitting electrode 35 and the first front surface electrode 61S.

(1-4) The second light emitting electrode 35 and the first front surface electrode 61S are bonded by the conductive bonding material SD.

With this configuration, a heat transfer path from the second light emitting electrode 35 to the first front surface electrode 61S becomes larger as compared to a configuration in which the second light emitting electrode 35 and the first front surface electrode 61S are connected by a wire. Therefore, heat is easily transferred from the edge light emitting element 30 to the first front surface electrode 61S.

(1-5) The second light emitting surface 33B of the edge light emitting element 30 includes the emission region 36. The light receiving region 49 of the light receiving element 40 faces the emission region 36.

With this configuration, the light receiving region 49 can easily receive the second laser light emitted from the emission region 36.

(1-6) The area of the light receiving region 49 is larger than the area of the emission region 36.

With this configuration, even when displacement occurs in the arrangement positions of the edge light emitting element 30 and the light receiving element 40, it is possible to maintain the state in which the light receiving region 49 faces the emission region 36.

(1-7) The center of the light receiving region 49 faces the emission region 36.

With this configuration, even when displacement occurs in the arrangement positions of the edge light emitting element 30 and the light receiving element 40, it is possible to maintain the state in which the light receiving region 49 faces the emission region 36.

(1-8) The substrate 20 has the substrate back surface 22 facing opposite to the substrate front surface 21 in the Z direction. The semiconductor light emitting device 10 includes the first to fourth back surface electrodes 61R to 64R formed on the substrate back surface 22.

With this configuration, the semiconductor light emitting device 10 has a surface-mounted package structure. Therefore, the heat of the edge light emitting element 30 is easily transferred to the outside of the semiconductor light emitting device 10 via the first back surface electrode 61R.

### Second Embodiment

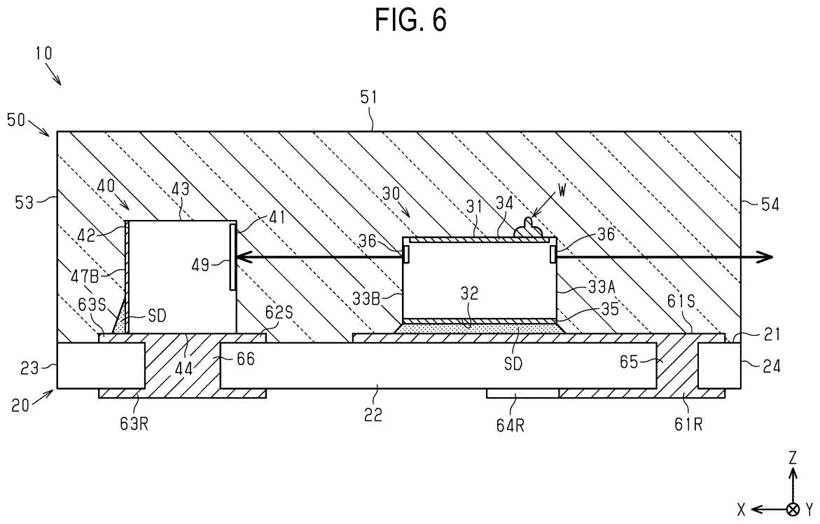

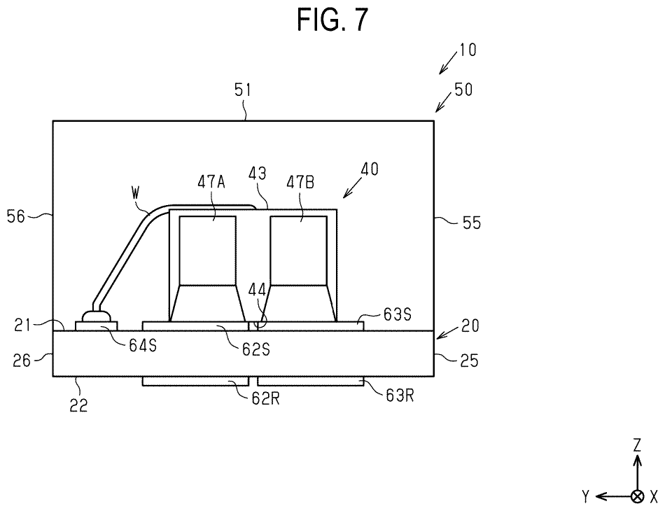

A semiconductor light emitting device 10 of a second embodiment will be described with reference to FIGS. 6 and 7. The semiconductor light emitting device 10 of the second embodiment is different from the semiconductor light emitting device 10 of the first embodiment in terms of the positions of the first light receiving electrode 47A and the second light receiving electrode 47B. Hereinafter, points different from the semiconductor light emitting device 10 of the first embodiment will be described in detail, and the same components as in the semiconductor light emitting device 10 of the first embodiment are denoted by the same reference numerals, and detailed explanation thereof will be omitted. FIG. 6 shows a schematic cross-sectional structure of the semiconductor light emitting device 10 taken along the XZ plane. FIG. 7 shows a schematic side structure of the semiconductor light emitting device 10 viewed from the X direction.

As shown in FIGS. 6 and 7, in the semiconductor light emitting device 10 of the second embodiment, the light receiving element 40 includes the second element back surface 42 opposite to the second element front surface 41, and the first light receiving electrode 47A and the second light receiving electrode 47B that are formed on the second element back surface 42 and spaced apart from each other. The first light receiving electrode 47A is electrically connected to the second front surface electrode 62S, and the second light receiving electrode 47B is electrically connected to the third front surface electrode 63S. Similar to the first embodiment, the first light receiving electrode 47A is bonded to the second front surface electrode 62S by the conductive bonding material SD, and the second light receiving electrode 47B is bonded to the third front surface electrode 63S by the conductive bonding material SD. In the second embodiment, the first light receiving electrode 47A is not formed on the second element front surface 41. That is, the conductive bonding material SD is not provided on the second element front surface 41 of the light receiving element 40, which is on a side of the edge light emitting element 30.

The first light receiving electrode 47A and the second light receiving electrode 47B are arranged in a direction intersecting an arrangement direction (X direction) of the edge light emitting element 30 and the light receiving element 40 in a plan view. In the example shown in FIG. 7, the first light receiving electrode 47A and the second light receiving electrode 47B are formed to be spaced apart from each other in the Y direction. In the example shown in FIG. 7, the first light receiving electrode 47A is provided to be closer to the fourth substrate side surface 26 than the second light receiving electrode 47B in the Y direction. The arrangement of the first light receiving electrode 47A and the second light receiving electrode 47B on the second element back surface 42 can be arbitrarily changed. In one example, the first light receiving electrode 47A and the second light receiving electrode 47B may be formed to be spaced apart from each other in the Z direction.

In the example shown in FIG. 7, an arrangement mode of the second front surface electrode 62S and the third front surface electrode 63S is different from that in the first embodiment according to the change in the positions of the first light receiving electrode 47A and the second light receiving electrode 47B. In one example, the second front surface electrode 62S and the third front surface electrode 63S are arranged to be spaced apart from each other in the Y direction. The second front surface electrode 62S is disposed to be closer to the fourth substrate side surface 26 than the third front surface electrode 63S.

### [Effect]

According to the second embodiment, the following effect can be obtained.

(2-1) The light receiving element 40 includes the first light receiving electrode 47A and the second light receiving electrode 47B that are formed on the second element back surface 42 and spaced apart from each other. The first light receiving electrode 47A is electrically connected to the second front surface electrode 62S. The second light receiving electrode 47B is electrically connected to the third front surface electrode 63S.

With this configuration, since no light receiving electrode is provided on the second element front surface 41 facing the second light emitting surface 33B, when the first light receiving electrode 47A and the second light receiving electrode 47B are bonded to the second front surface electrode 62S and the third front surface electrode 63S, respectively, by the conductive bonding material SD, irradiation of the conductive bonding material SD with the second laser light is suppressed. Thus, reflected light of the second laser light by the conductive bonding material SD is suppressed from entering the light receiving region 49.

Therefore, it is possible to improve accuracy of output control of the first laser light based on the amount of light received by the light receiving region 49.

### Third Embodiment

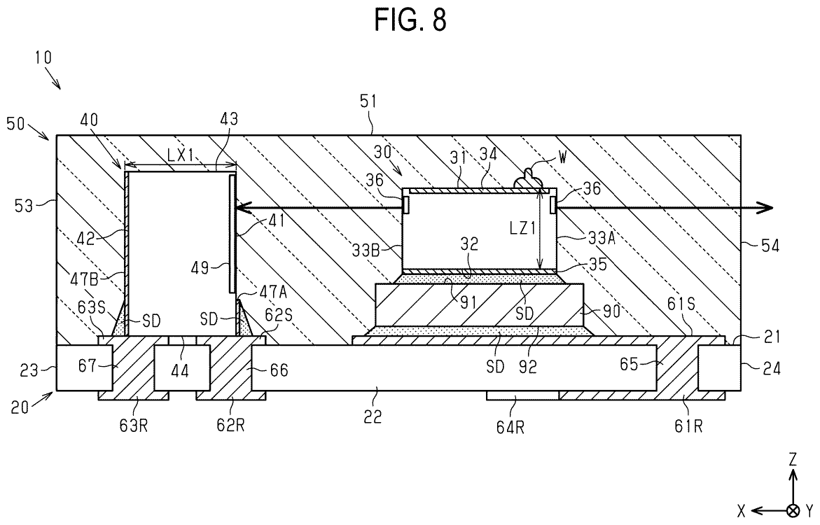

A semiconductor light emitting device 10 of a third embodiment will be described with reference to FIG. 8. The semiconductor light emitting device 10 of the third embodiment is mainly different from the semiconductor light emitting device 10 of the first embodiment in that the former includes a sub-mount substrate 90 provided between the substrate 20 and the edge light emitting element 30. Hereinafter, differences between the semiconductor light emitting device 10 of the third embodiment and the semiconductor light emitting device 10 of the first embodiment will be described in detail, and the same components as in the semiconductor light emitting device 10 of the first embodiment are denoted by the same reference numerals, and detailed explanation thereof will be omitted. FIG. 8 shows a schematic cross-sectional structure of the semiconductor light emitting device 10 taken along the XZ plane.

As shown in FIG. 8, the semiconductor light emitting device 10 includes the sub-mount substrate 90 interposed between the substrate 20 and the edge light emitting element 30 in the Z direction. The sub-mount substrate 90 is formed in a rectangular flat plate shape having the Z direction as a thickness direction. The sub-mount substrate 90 is made of, for example, a conductive material. As the conductive material, for example, Cu, Al, and the like are used. In one example, the sub-mount substrate 90 is made of Cu.

As shown in FIG. 8, the sub-mount substrate 90 has a sub-mount front surface 91 and a sub-mount back surface 92 that face opposite to each other. The sub-mount front surface 91 faces the same side as the substrate front surface 21 of the substrate 20, and the sub-mount back surface 92 faces the same side as the substrate back surface 22 of the substrate 20.

The sub-mount substrate 90 is bonded to the first front surface electrode 61S by the conductive bonding material SD. The conductive bonding material SD is in contact with the sub-mount back surface 92. In a plan view, a dimension of the sub-mount substrate 90 in the X direction is larger than a dimension of the edge light emitting element 30 in the X direction, and a dimension of the sub-mount substrate 90 in the Y direction is larger than a dimension of the edge light emitting element 30 in the Y direction.

In the example shown in FIG. 8, a thickness LX1 of the light receiving element 40 is larger than a thickness LZ1 of the sub-mount substrate 90. Here, the thickness LX1 of the light receiving element 40 can be defined by a distance between the second element front surface 41 and the second element back surface 42 in the X direction. At least a portion of the second light emitting surface 33B is disposed to face the light receiving region 49 of the light receiving element 40 in the Z direction. The relationship between the thickness LX1 and the thickness LZ1 can be arbitrarily changed. In one example, the thickness LX1 may be equal to the thickness LZ1. Further, in one example, the thickness LX1 may be smaller than the thickness LZ1.

The edge light emitting element 30 is disposed on the sub-mount substrate 90. The edge light emitting element 30 is bonded to the sub-mount substrate 90 by the conductive bonding material SD. This conductive bonding material SD is in contact with the sub-mount front surface 91.

In the third embodiment, the seal 50 seals the light receiving element 40, the sub-mount substrate 90, and at least a portion of the edge light emitting element 30. Further, in the example shown in FIG. 8, the seal 50 seals the wire W. Here, the seal 50 is an example of a “cover.” In the third embodiment, the seal 50 seals the entire edge light emitting element 30.

### [Effects]

According to the semiconductor light emitting device 10 of the third embodiment, the following effects can be obtained.

(3-1) The semiconductor light emitting device 10 further includes the sub-mount substrate 90, which is interposed between the first front surface electrode 61S and the edge light emitting element 30 in the thickness direction and is in contact with the first front surface electrode 61S and the second light emitting electrode 35.

With this configuration, since the edge light emitting element 30 is provided on the sub-mount substrate 90, the heat of the edge light emitting element 30 is easily transferred to the substrate 20 via the sub-mount substrate 90. Therefore, it is possible to suppress the temperature of the edge light emitting element 30 from becoming excessively high.

In addition, a height of the edge light emitting element 30 can be adjusted by the thickness of the sub-mount substrate 90 so that at least a portion of the second laser light from the second light emitting surface 33B of the edge light emitting element 30 enters the light receiving region 49. Therefore, it is easy to cause the light receiving element 40 to receive at least a portion of the second laser light from the edge light emitting element 30.

(3-2) The sub-mount substrate 90 is made of a conductive material.

With this configuration, the second light emitting electrode 35 and the first front surface electrode 61S are electrically connected to each other via the sub-mount substrate 90. Therefore, as compared to a configuration in which the second light emitting electrode 35 and the first front surface electrode 61S are connected to each other by a wire passing outside the sub-mount substrate 90, it is possible to shorten a length of a conductive path between the second light emitting electrode 35 and the first front surface electrode 61S.

### Fourth Embodiment

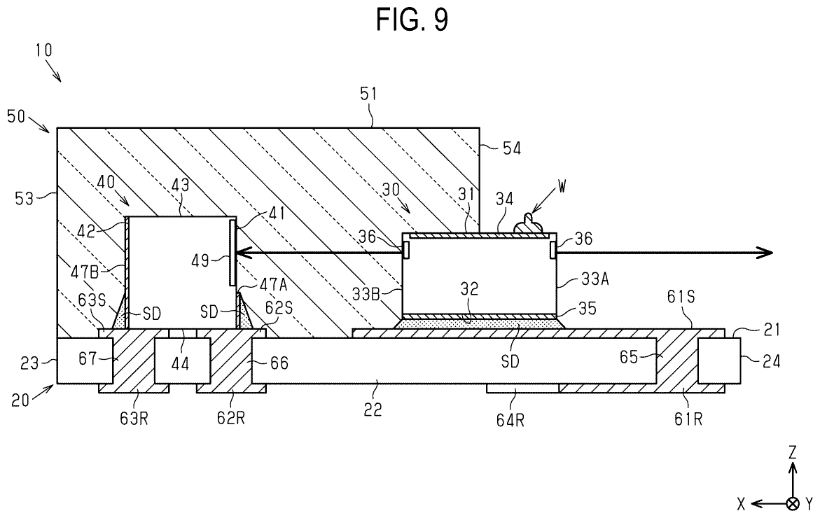

A semiconductor light emitting device 10 of a fourth embodiment will be described with reference to FIG. 9. The semiconductor light emitting device 10 of the fourth embodiment is mainly different from the semiconductor light emitting device 10 of the first embodiment in terms of the configuration of the seal 50. Hereinafter, points different from the semiconductor light emitting device 10 of the first embodiment will be described in detail, and the same components as in the semiconductor light emitting device 10 of the first embodiment are denoted by the same reference numerals, and detailed explanation thereof will be omitted. FIG. 9 shows a schematic cross-sectional structure of the semiconductor light emitting device 10 taken along the XZ plane.

As shown in FIG. 9, the seal 50 of the fourth embodiment is provided so as to seal the second light emitting surface 33B of the edge light emitting element 30 while exposing the first light emitting surface 33A. More specifically, the second sealing side surface 54 is disposed to be closer to the first substrate side surface 23 than the first light emitting surface 33A of the edge light emitting element 30. As a result, the first light emitting surface 33A is exposed from the seal 50. On the other hand, the second sealing side surface 54 is disposed to be closer to the second substrate side surface 24 than the second light emitting surface 33B of the edge light emitting element 30. As a result, the second light emitting surface 33B is sealed by the seal 50. Further, the light receiving region 49 of the light receiving element 40 is sealed by the seal 50. In the example shown in FIG. 9, the seal 50 seals the entire light receiving element 40. As described above, the seal 50 seals at least the second light emitting surface 33B of the edge light emitting element 30 and the light receiving region 49 of the light receiving element 40.

As shown in FIG. 9, the wire W is exposed from the seal 50. Therefore, a portion of the first light emitting electrode 34 of the edge light emitting element 30, a portion of the first front surface electrode 61S, and a portion of the fourth front surface electrode 64S are exposed from the seal 50. That is, the wire W electrically connects the first light emitting electrode 34 and the fourth front surface electrode 64S outside the seal 50.

### [Effects]

According to the semiconductor light emitting device 10 of the fourth embodiment, the following effects can be obtained.

(4-1) The seal 50 exposes the first light emitting surface 33A of the edge light emitting element 30.

With this configuration, since the first laser light from the first light emitting surface 33A is emitted to the outside of the semiconductor light emitting device 10 without passing through the seal 50, it is possible to suppress the first laser light from spreading by the seal 50.

(4-2) The wire W is provided outside the seal 50.

With this configuration, as compared to a configuration in which the seal 50 seals the wire W, it is possible to suppress a stress from being applied to the wire W due to a difference in thermal expansion coefficient between the seal 50 and the wire W when a temperature change occurs.

### Fifth Embodiment

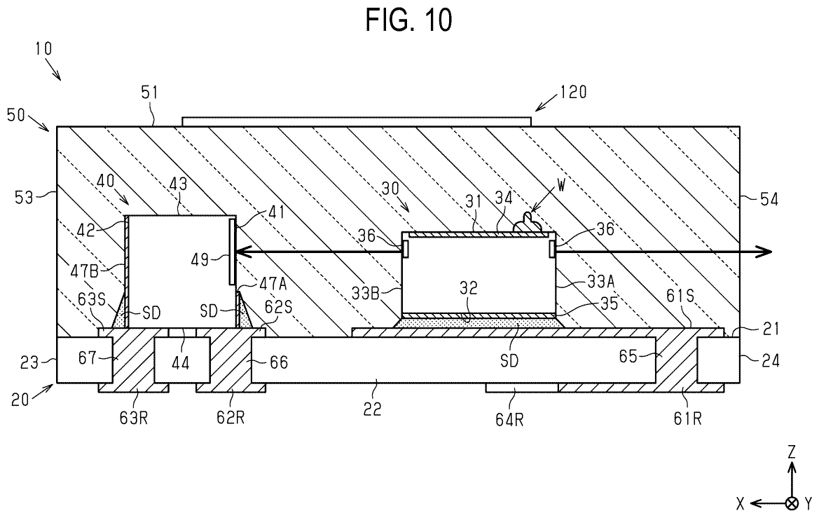

A semiconductor light emitting device 10 of a fifth embodiment will be described with reference to FIG. 10. The semiconductor light emitting device 10 of the fifth embodiment is mainly different from the semiconductor light emitting device 10 of the first embodiment in that the former includes a light shielding layer provided on the sealing front surface 51 of the seal 50. Hereinafter, points different from the semiconductor light emitting device 10 of the first embodiment will be described in detail, and the same components as in the semiconductor light emitting device 10 of the first embodiment are denoted by the same reference numerals, and detailed explanation thereof will be omitted. FIG. 10 shows a schematic cross-sectional structure of the semiconductor light emitting device 10 taken along the XZ plane.

As shown in FIG. 10, in the fifth embodiment, a light shielding layer 120 is provided on the sealing front surface 51 of the seal 50 between the second light emitting surface 33B of the edge light emitting element 30 and the second element front surface 41 of the light receiving element 40 in a plan view. The light shielding layer 120 is provided, for example, so as to cover both the second light emitting surface 33B and the second element front surface 41 in a plan view. In the example shown in FIG. 10, the light shielding layer 120 is disposed to be closer to the first sealing side surface 53 than the first light emitting surface 33A. That is, the light shielding layer 120 does not cover the first light emitting surface 33A in a plan view.

Although not shown, a dimension of the light shielding layer 120 in the Y direction is equal to or larger than, for example, a dimension of the light receiving region 49 of the light receiving element 40 in the Y direction. Further, the dimension of the light shielding layer 120 in the Y direction is equal to or larger than, for example, a dimension of the emission region 36 of the second light emitting surface 33B in the Y direction. Further, the dimension of the light shielding layer 120 in the Y direction may be equal to or larger than, for example, a dimension of the light receiving element 40 in the Y direction. Further, the dimension of the light shielding layer 120 in the Y direction may be equal to or larger than, for example, a dimension of the edge light emitting element 30 in the Y direction. Further, the dimension of the light shielding layer 120 in the Y direction may be equal to a dimension of the seal 50 in the Y direction.

The light shielding layer 120 may be made of, for example, a resin material having light shielding properties. For example, black epoxy resin is used as the resin material having light shielding properties. Further, the light shielding layer 120 may be formed of, for example, a metal film. Further, the light shielding layer 120 may be formed of an antireflection film (AR coat). A shape of the light shielding layer 120 can be arbitrarily changed.

In addition, the arrangement position and size of the light shielding layer 120 can be arbitrarily changed. In one example, since it is only necessary that the light shielding layer 120 is provided so that light from the outside of the semiconductor light emitting device 10 does not enter the light receiving region 49, it is not necessary that the light shielding layer 120 covers the second light emitting surface 33B in a plan view. Further, the light shielding layer 120 does not need to cover the light receiving region 49 in a plan view when the light does not enter the light receiving region 49. In one example, the light shielding layer 120 may be disposed on the sealing front surface 51 at a position adjacent to the light receiving region 49 in the X direction in a plan view. Each of the dimensions of the light shielding layer 120 in the X direction and the Y direction can be arbitrarily changed.

### [Effect]

According to the semiconductor light emitting device 10 of the fifth embodiment, the following effect can be obtained.

(5-1) The seal 50 has the sealing front surface 51 facing the same side as the substrate front surface 21, and when viewed from the thickness direction, the light shielding layer 120 is provided on the sealing front surface 51 between the second light emitting surface 33B and the second element front surface 41.

With this configuration, it is possible to suppress light from the outside from entering the light receiving region 49. This reduces noise caused by external light. Thus, it is possible to improve the accuracy of output control of the first laser light based on the amount of light received by the light receiving region 49.

### Sixth Embodiment

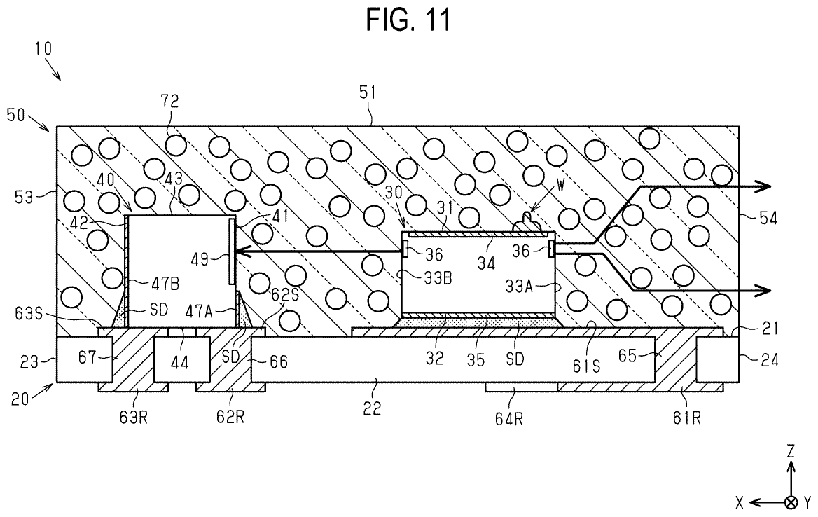

A semiconductor light emitting device 10 of a sixth embodiment will be described with reference to FIG. 11. The semiconductor light emitting device 10 of the sixth embodiment is mainly different from the semiconductor light emitting device 10 of the first embodiment in terms of the configuration of the seal 50. Hereinafter, points different from the semiconductor light emitting device 10 of the first embodiment will be described in detail, and the same components as in the semiconductor light emitting device 10 of the first embodiment are denoted by the same reference numerals, and detailed explanation thereof will be omitted. FIG. 11 shows a schematic cross-sectional structure of the semiconductor light emitting device 10 taken along the XZ plane.

As shown in FIG. 11, the seal 50 of the sixth embodiment includes diffusers 72. The diffusers 72 diffuse light inside the seal 50 by reflecting (scattering) the light at interfaces between resin and the diffusers 72 in the seal 50.

Material of the diffusers 72 is not particularly limited, but can be, for example, silica or other glass materials. In one example, spherical silica filler is used as the diffusers 72. A particle size of the diffusers 72 is not particularly limited but, for example, is selected to be sufficiently small with respect to wavelengths of the first laser light and the second laser light emitted from the edge light emitting element 30 so that scattering occurs dominantly.

The diffusers 72 are dispersed as fine particles in the seal 50. The diffusers 72 are mixed at a predetermined mixing ratio with respect to the seal 50. In one example, the diffusers 72 are evenly dispersed inside the seal 50. The mixing ratio of the diffusers 72 to the resin of the seal 50 is not particularly limited, and may be more than 0% and less than 100%. As the mixing ratio of the diffusers 72 increases, the light receiving element 40 receives scattered light more easily, so that a directional angle of the first laser light of the edge light emitting element 30 can be widened. Further, by limiting an upper limit of the mixing ratio of the diffusers 72 to a predetermined value, it is possible to suppress the output and radiation intensity of the laser light (the first laser light) of the semiconductor light emitting device 10 from decreasing significantly. In one example, the diffusers 72 are selected to have a smaller coefficient of thermal expansion than, for example, the resin of the seal 50.

### [Effects]

According to the semiconductor light emitting device 10 of the sixth embodiment, the following effects can be obtained.

(6-1) The seal 50 includes the diffusers 72 that are provided inside the seal 50 and diffuse the laser light emitted by the edge light emitting element 30.

With this configuration, the light receiving element 40 receives a part of the laser light, which is diffused by the diffusers 72 inside the seal 50, among the second laser light emitted from the second light emitting surface 33B of the edge light emitting element 30. Thus, even when displacement occurs in the arrangement positions of the edge light emitting element 30 and the light receiving element 40, the light receiving element 40 receives the second laser light easily. In addition, by diffusing the first laser light from the first light emitting surface 33A of the edge light emitting element 30 by the diffusers 72, it is possible to widen the directional angle of the first laser light. Therefore, it is possible to widen the directional angle of the laser light of the semiconductor light emitting device 10.

(6-2) The diffusers 72 are selected to have a smaller coefficient of thermal expansion than, for example, the resin of the seal 50.

With this configuration, as compared to a configuration in which the seal 50 does not include the diffusers 72, it is possible to reduce a thermal stress, which is generated in the seal 50, by the diffusers 72. As a result, it is possible to reduce a stress applied to the wire W due to the thermal stress of the seal 50.

### Seventh Embodiment

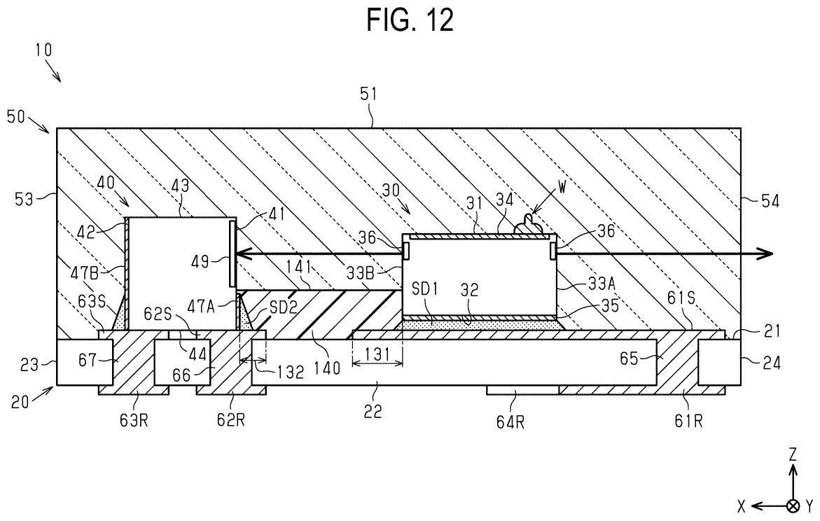

A semiconductor light emitting device 10 of a seventh embodiment will be described with reference to FIG. 12. The seventh embodiment is mainly different from the first embodiment in that the former includes an antireflection layer provided between the edge light emitting element 30 and the light receiving element 40 on the substrate front surface 21. Hereinafter, points different from the semiconductor light emitting device 10 of the sixth embodiment will be described in detail, and the same components as in the semiconductor light emitting device 10 of the first embodiment are denoted by the same reference numerals, and detailed explanation thereof will be omitted. FIG. 12 shows a schematic cross-sectional structure of the semiconductor light emitting device 10 taken along the XZ plane.

As shown in FIG. 12, the first front surface electrode 61S includes a first protrusion 131 that protrudes from the second light emitting surface 33B toward the light receiving element 40 in a plan view. The second front surface electrode 62S includes a second protrusion 132 that protrudes from the second element front surface 41 toward the edge light emitting element 30 in a plan view. The first protrusion 131 is provided with a first conductive bonding material SD1 for bonding the second light emitting electrode 35 and the first front surface electrode 61S, and the second protrusion 132 is provided with a second conductive bonding material SD2 for bonding the first light receiving electrode 47A and the second front surface electrode 62S. The same bonding material as, for example, the conductive bonding material SD of the first embodiment may be used for both the first conductive bonding material SD1 and the second conductive bonding material SD2.

As shown in FIG. 12, in the seventh embodiment, an antireflection layer 140 covering the first conductive bonding material SD1, the second conductive bonding material SD2, the first protrusion 131, and the second protrusion 132 is provided on the substrate front surface 21. The antireflection layer 140 is provided, for example, between the second light emitting surface 33B of the edge light emitting element 30 and the second element front surface 41 of the light receiving element 40 in a plan view. The antireflection layer 140 is provided to be closer to the substrate 20 than the light receiving region 49 in the Z direction. In other words, the antireflection layer 140 has an antireflection layer front surface 141 facing the same side as the sealing front surface 51 in the Z direction, and the antireflection layer front surface 141 is located to be closer to the substrate 20 than a portion of the light receiving region 49 that is closest to the substrate 20 in the Z direction. Further, as shown in FIG. 12, in one example, the antireflection layer 140 is provided so as to cover the first light receiving electrode 47A. In other words, the antireflection layer front surface 141 is located to be closer to the sealing front surface 51 than a portion of the first light receiving electrode 47A that is closest to the sealing front surface 51 in the Z direction. Further, as shown in FIG. 12, for example, the antireflection layer 140 is in contact with the second light emitting surface 33B of the edge light emitting element 30 and the second element front surface 41 of the light receiving element 40.

Although not shown, a dimension of the antireflection layer 140 in the Y direction is equal to or larger than, for example, dimensions of the first conductive bonding material SD1, the second conductive bonding material SD2, the first protrusion 131, and the second protrusion 132 in the Y direction. Further, the dimension of the antireflection layer 140 in the Y direction may be equal to a dimension of the seal 50 in the Y direction.

For example, black resin is used as the antireflection layer 140. Further, the antireflection layer 140 may be formed by an anti-reflection coating (AR coat). The antireflection layer 140 is formed, for example, in a rectangular shape in a plan view. The shape of the antireflection layer 140 in a plan view can be arbitrarily changed.

In addition, the arrangement position and size of the antireflection layer 140 can be arbitrarily changed. In one example, since it is only necessary that the antireflection layer 140 is provided so that reflected light from the first conductive bonding material SD1, the second conductive bonding material SD2, the first protrusion 131, and the second protrusion 132 does not enter the light receiving region 49, it is not necessary that the antireflection layer 140 is in contact with the substrate front surface 21. Further, the antireflection layer 140 does not need to be provided to cover the first light receiving electrode 47A when the light does not enter the light receiving region 49. The dimension of the antireflection layer 140 in the Y direction can be arbitrarily changed.

### [Effects]

According to the semiconductor light emitting device 10 of the seventh embodiment, the following effects can be obtained.

(7-1) The semiconductor light emitting device 10 includes the antireflection layer 140 that covers both the first protrusion 131 of the first front surface electrode 61S and the second protrusion 132 of the second front surface electrode 62S.

With this configuration, it is possible to suppress light reflected by either the first protrusion 131 or the second protrusion 132 from entering the light receiving region 49. Therefore, it is possible to reduce noise with respect to the amount of light received by the light receiving region 49 and improve the accuracy of output control of the first laser light based on the amount of light received by the light receiving region 49.

(7-2) The first protrusion 131 is provided with the first conductive bonding material SD1 for bonding the second light emitting electrode 35 and the first front surface electrode 61S. The second protrusion 132 is provided with the second conductive bonding material SD2 for bonding the first light receiving electrode 47A and the second front surface electrode 62S. The antireflection layer 140 covers both the first conductive bonding material SD1 and the second conductive bonding material SD2.

With this configuration, it is possible to suppress light reflected by either the first conductive bonding material SD1 or the second conductive bonding material SD2 from entering the light receiving region 49. Therefore, since noise with respect to the amount of light received by the light receiving region 49 can be reduced, it is possible to improve the accuracy of output control of the first laser light based on the amount of light received by the light receiving region 49.

### Eighth Embodiment

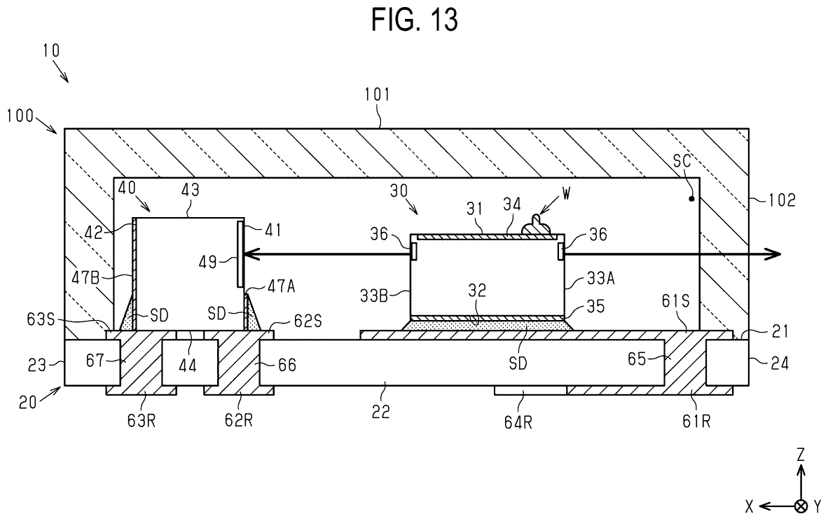

A semiconductor light emitting device 10 of an eighth embodiment will be described with reference to FIG. 13. The semiconductor light emitting device 10 of the eighth embodiment is mainly different from the semiconductor light emitting device 10 of the first embodiment in terms of a configuration of the seal 50. Hereinafter, points different from the semiconductor light emitting device 10 of the first embodiment will be described in detail, and the same components as in the semiconductor light emitting device 10 of the first embodiment are denoted by the same reference numerals, and detailed explanation thereof will be omitted. FIG. 13 shows a schematic cross-sectional structure of the semiconductor light emitting device 10 taken along the XZ plane.

As shown in FIG. 13, the semiconductor light emitting device 10 of the eighth embodiment includes a case 100 as a cover instead of the seal 50 (see FIG. 1). The case 100 accommodates at least a portion of the edge light emitting element 30 and at least a portion of the light receiving element 40. In the example shown in FIG. 13, the case 100 accommodates the entire edge light emitting element 30 and the entire light receiving element 40. More specifically, the case 100 is provided on the substrate 20. The case 100 is attached to the substrate 20 by an adhesive, for example. A closed space SC is formed by the case 100 and the substrate front surface 21 of the substrate 20. The edge light emitting element 30 and the light receiving element 40 are disposed in the closed space SC.

The case 100 is formed in a box shape that is open toward the substrate 20. The case 100 includes a top wall 101 and four side walls 102. The top wall 101 is formed in a flat plate shape orthogonal to the Z direction. The four side walls 102 extend along the first to fourth substrate side surfaces 23 to 26 (see FIG. 1) in a plan view.

The case 100 is made of a material through which the first laser light and the second laser light of the edge light emitting element 30 can pass. The case 100 is made of a material containing at least one of, for example, silicone resin, epoxy resin, and acrylic resin. In one example, the case 100 is made of silicone resin.

### [Effect]

According to the semiconductor light emitting device 10 of the eighth embodiment, the following effect can be obtained.

(8-1) The semiconductor light emitting device 10 includes the case 100, which is provided on the substrate front surface 21 and accommodates the edge light emitting element 30 and the light receiving element 40.

With this configuration, the wire W is disposed in the closed space SC formed by the case 100 and the substrate 20. Therefore, it is possible to suppress a stress due to a temperature change from being applied to the wire W.

### Modifications

Each of the above-described embodiments can be modified and implemented as follows. Further, each of the above-described embodiments and the following modifications can be implemented in combination with one another unless technically contradictory.

The first to eighth embodiments can be combined with one another unless technically contradictory.

In one example, in the first to fifth embodiments and the seventh embodiment, the seal 50 may include the diffusers 72 of the sixth embodiment.

In one example, in the first embodiment, the second embodiment, and the fourth to eighth embodiments, the semiconductor light emitting device 10 may include the sub-mount substrate 90.

In one example, in the first to seventh embodiments, the semiconductor light emitting device 10 may include the case 100 instead of the seal 50.

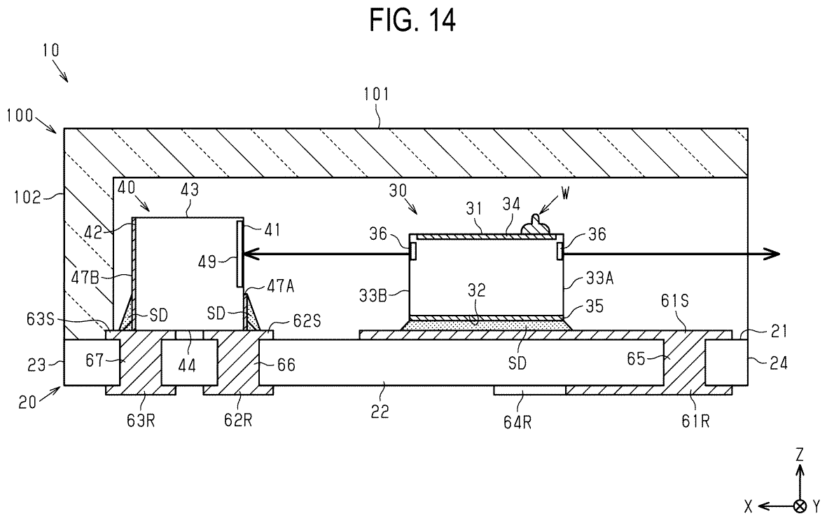

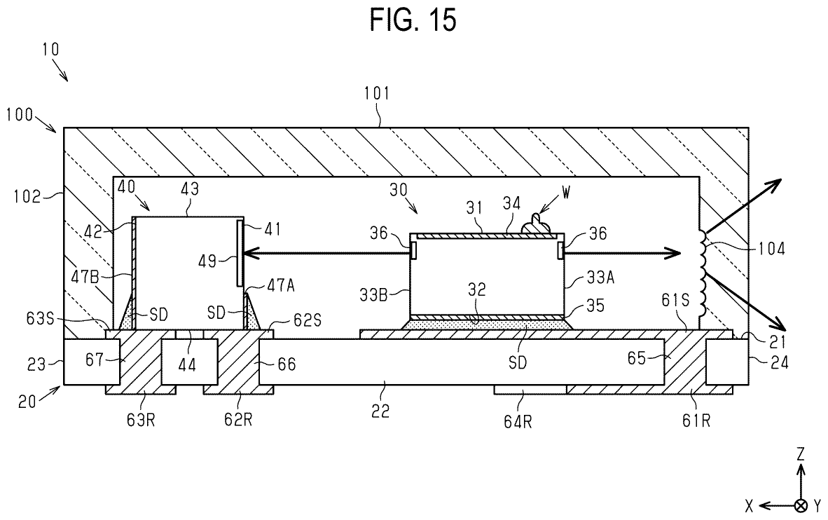

In the eighth embodiment, the configuration of the case 100 can be arbitrarily changed. In one example, the case 100 may be modified to have a configuration of a first example shown in FIG. 14 or a configuration of a second example shown in FIG. 15.

As shown in FIG. 14, in the case 100 of the first example, one of the four side walls 102 that faces the first light emitting surface 33A of the edge light emitting element 30 may be omitted. The side wall 102 facing the first light emitting surface 33A is a side wall along the second substrate side surface 24 of the substrate 20 in a plan view. With this configuration, since the first laser light from the second light emitting surface 33B does not pass through the side wall 102, the first laser light can be emitted to the outside of the semiconductor light emitting device 10 without being diffused by the side wall 102.

As shown in FIG. 15, in the case 100 of the second example, a light diffuser 104 that diffuses the first laser light may be formed on one of the four side walls 102 that faces the first light emitting surface 33A of the edge light emitting element 30, that is, the side wall 102 through which the first laser light passes. The light diffuser 104 is formed, for example, in a region, which faces the first light emitting surface 33A in the X direction, of the side wall 102 through which the first laser light passes. The light diffuser 104 includes, for example, as shown in FIG. 15, unevenness formed on an inner surface of one of the four side walls 102 that faces the first light emitting surface 33A of the edge light emitting element 30. The unevenness constituting the light diffuser 104 includes, for example, curved concave surfaces, which are concaved from the inner surface of the side wall 102 in a curved shape.

With this configuration, by diffusing the first laser light by the light diffuser 104, it is possible to widen the directional angle of the first laser light. Therefore, it is possible to widen the directional angle of the laser light of the semiconductor light emitting device 10.

In addition, the formation region of the light diffuser 104 can be arbitrarily changed. The formation region of the light diffuser 104 may cover the entire first light emitting surface 33A and may be larger than an area of the first light emitting surface 33A when viewed from the X direction. In one example, the light diffuser 104 may be formed over the entire side wall 102 through which the first laser light passes. A configuration of the light diffuser 104 can be arbitrarily changed as long as it can diffuse the first laser light. In one example, one of the four side walls 102 that faces the first light emitting surface 33A of the edge light emitting element 30 includes a flat surface that is the inner surface of the side wall 102 other than the light diffuser 104, and a rough surface that is the inner surface constituting the light diffuser 104 and is rougher than the flat surface.

In the first to fourth embodiments and the sixth and seventh embodiments, the light shielding layer 120 may be provided on the front surface of the seal 50. The light shielding layer 120 covers the light receiving region 49 of the light receiving element 40 when viewed from the thickness direction of the substrate 20, for example. The light shielding layer 120 may be made of, for example, a resin material having light shielding properties. For example, black epoxy resin is used as the resin material having light shielding properties. Further, the light shielding layer 120 may be formed of, for example, a metal film. Further, the light shielding layer 120 may be formed by an anti-reflection coating (AR coat). The light shielding layer 120 has, for example, a rectangular shape when viewed from a direction perpendicular to the sealing front surface 51. The shape of the light shielding layer 120 viewed from the direction perpendicular to the sealing front surface 51 can be arbitrarily changed.

In the eighth embodiment, the light shielding layer 120 may be provided on an outer surface of the case 100. The light shielding layer 120 covers the light receiving region 49 of the light receiving element 40 when viewed from the thickness direction of the substrate 20, for example. The light shielding layer 120 has, for example, a rectangular shape when viewed from a direction perpendicular to the sealing front surface 51. The shape of the light shielding layer 120 viewed from the direction perpendicular to the sealing front surface 51 can be arbitrarily changed.

In the eighth embodiment, the case 100 is provided to accommodate the entire edge light emitting element 30 and the entire light receiving element 40, but is not limited thereto. In one example, the case 100 may be provided so as to accommodate a portion of the edge light emitting element 30 and a portion of the light receiving element 40, and the other portion of the edge light emitting element 30 and the other portion of the light receiving element 40 may be located outside the case 100.

In the first to seventh embodiments, a material constituting the seal 50 can be arbitrarily changed. In one example, the seal 50 may be made of a material that blocks visible light and transmits laser light having a specific wavelength different from visible light. The laser light of the specific wavelength is, for example, ultraviolet laser. For example, a visible light-shielding silicone sealing material may be used as the material constituting the seal 50. For example, AIR-7051-A/B (manufactured by Shin-Etsu Chemical Co., Ltd.) may be used as this sealing material. In this case, the edge light emitting element 30 is configured to emit laser light having a specific wavelength different from visible light.

In the third embodiment, the sub-mount substrate 90 may be made of an insulating material. Examples of the insulating material may include epoxy resin, ceramic, and the like. Examples of the ceramic may include AlN, Al₂O₃, and the like. In this case, the sub-mount substrate 90 may include a through-wiring that penetrates the sub-mount substrate 90 in the Z direction which is the thickness direction of the sub-mount substrate 90. One through-wiring or a plurality of through-wirings may be provided. Further, the sub-mount substrate 90 may be made of a material containing, for example, silicon (Si). Also in this case, the sub-mount substrate 90 may include the above-mentioned through-wiring.

In the eighth embodiment, the material constituting the case 100 can be arbitrarily changed. In one example, the case 100 may be made of a material that blocks visible light and transmits laser light having a specific wavelength different from visible light. The laser light of the specific wavelength is, for example, ultraviolet laser. For example, a visible light-shielding silicone sealing material may be used as the material constituting the case 100. For example, AIR-7051-A/B (manufactured by Shin-Etsu Chemical Co., Ltd.) may be used as this sealing material. In this case, the edge light emitting element 30 is configured to emit laser light having a specific wavelength different from visible light.

In each embodiment, the relationship between the area of the emission region 36 of the second light emitting surface 33B of the edge light emitting element 30 and the area of the light receiving region 49 of the light receiving element 40 can be arbitrarily changed. In one example, the area of the emission region 36 and the area of the light receiving region 49 may be equal to each other. Further, in one example, the area of the light receiving region 49 may be smaller than the area of the emission region 36.

In each embodiment, the relationship between the dimension of the emission region 36 of the second light emitting surface 33B of the edge light emitting element 30 in the Z direction and the dimension of the light receiving region 49 of the light receiving element 40 in the Z direction can be arbitrarily changed. In one example, the dimension of the emission region 36 in the Z direction and the dimension of the light receiving region 49 in the Z direction may be equal to each other. Further, in one example, the dimension of the light receiving region 49 in the Z direction may be smaller than the dimension of the emission region 36 in the Z direction.

In each embodiment, as long as the laser light from the emission region 36 of the second light emitting surface 33B can be received by the light receiving region 49 of the light receiving element 40, the light receiving region 49 may be disposed at a position that is slightly shifted from the emission region 36 and does not face the emission region 36.

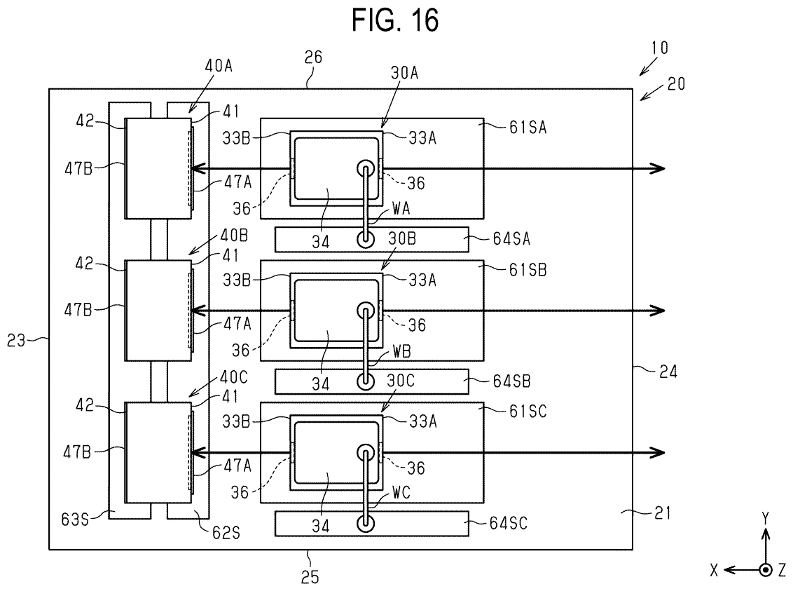

In each embodiment, a plurality of edge light emitting elements 30 and a plurality of light receiving elements 40 may be provided. First to sixth modifications having configurations in which the semiconductor light emitting device 10 includes the plurality of edge light emitting elements 30 and the plurality of light receiving elements 40 will be described with reference to FIGS. 16 to 22.

### First Modification

As shown in FIG. 16, a semiconductor light emitting device 10 of a first modification includes a first edge light emitting element 30A, a second edge light emitting element 30B, and a third edge light emitting element 30C as a plurality of edge light emitting elements 30, and a first light receiving element 40A, a second light receiving element 40B, and a third light receiving element 40C as a plurality of light receiving elements 40. Further, the semiconductor light emitting device 10 of the first modification includes a plurality of first front surface electrodes 61SA to 61SC and a plurality of fourth front surface electrodes 64SA to 64SC according to the number of edge light emitting elements 30. On the other hand, the number of the second front surface electrode 62S and the number of the third front surface electrode 63S are the same as in each embodiment. In other words, the second front surface electrode 62S and the third front surface electrode 63S serve as common front surface electrodes for the first to third light receiving elements 40A to 40C.

The first front surface electrodes 61SA to 61SC and the fourth front surface electrodes 64SA to 64SC are alternately disposed one by one in the Y direction. Both the second front surface electrode 62S and the third front surface electrode 63S extend along the Y direction.

The first edge light emitting element 30A is mounted on the first front surface electrode 61SA. The first light emitting electrode 34 of the first edge light emitting element 30A and the fourth front surface electrode 64SA are connected by a wire WA. Therefore, the second light emitting electrode 35 (see FIG. 3) of the first edge light emitting element 30A is electrically connected to the first front surface electrode 61SA, and the first light emitting electrode 34 of the first edge light emitting element 30A is electrically connected to the fourth front surface electrode 64SA.

The second edge light emitting element 30B is mounted on the first front surface electrode 61SB. The first light emitting electrode 34 of the second edge light emitting element 30B and the fourth front surface electrode 64SB are connected by a wire WB. Therefore, the second light emitting electrode 35 of the second edge light emitting element 30B is electrically connected to the first front surface electrode 61SB, and the first light emitting electrode 34 of the second edge light emitting element 30B is electrically connected to the fourth front surface electrode 64SB.

The third edge light emitting element 30C is mounted on the first front surface electrode 61SC. The first light emitting electrode 34 of the third edge light emitting element 30C and the fourth front surface electrode 64SC are connected by a wire WC. Therefore, the second light emitting electrode 35 of the third edge light emitting element 30C is electrically connected to the first front surface electrode 61SC, and the first light emitting electrode 34 of the third edge light emitting element 30C is electrically connected to the fourth front surface electrode 64SC.

The first light receiving element 40A is disposed at a position facing the first edge light emitting element 30A in the Y direction. The second element front surface 41 of the first light receiving element 40A faces the second light emitting surface 33B of the first edge light emitting element 30A. The arrangement mode of the first light receiving element 40A and the first edge light emitting element 30A is similar to the arrangement mode of the light receiving element 40 and the edge light emitting element 30 of the first embodiment, for example.

The second light receiving element 40B is disposed at a position facing the second edge light emitting element 30B in the Y direction. The second element front surface 41 of the second light receiving element 40B faces the second light emitting surface 33B of the second edge light emitting element 30B. The arrangement mode of the second light receiving element 40B and the second edge light emitting element 30B is similar to the arrangement mode of the light receiving element 40 and the edge light emitting element 30 of the first embodiment, for example.

The third light receiving element 40C is disposed at a position facing the third edge light emitting element 30C in the Y direction. The second element front surface 41 of the third light receiving element 40C faces the second light emitting surface 33B of the third edge light emitting element 30C. The arrangement mode of the third light receiving element 40C and the third edge light emitting element 30C is similar to the arrangement mode of the light receiving element 40 and the edge light emitting element 30 of the first embodiment, for example.

Although not shown, the first light receiving electrode 47A of each of the first to third light receiving elements 40A to 40C is mounted on the second front surface electrode 62S, and the second light receiving electrode 47B of each of the first to third light receiving elements 40A to 40C is mounted on the third front surface electrode 63S. Thus, the first light receiving electrode 47A of each of the first to third light receiving elements 40A to 40C is electrically connected to the second front surface electrode 62S, and the second light receiving electrode 47B of each of the first to third light receiving elements 40A to 40C is electrically connected to the third front surface electrode 63S.

The semiconductor light emitting device 10 includes, for example, a seal 50 (not shown). Although not shown, the seal 50 seals each of the first to third edge light emitting elements 30A to 30C and the first to third light receiving elements 40A to 40C. The configuration of the seal 50 can be arbitrarily changed, and for example, the semiconductor light emitting device 10 may include the seal 50 of the sixth embodiment. Further, the semiconductor light emitting device 10 may include a case 100 (see FIG. 13) instead of the seal 50.

### Second Modification

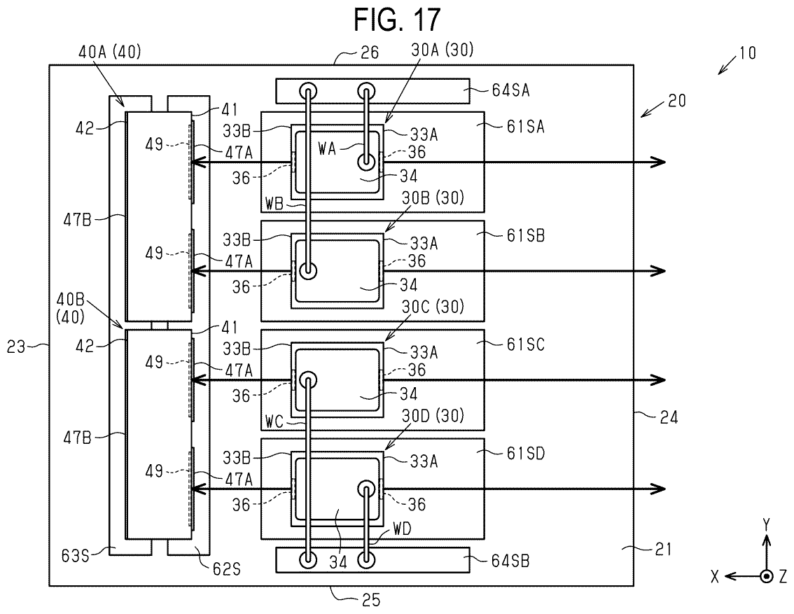

As shown in FIG. 17, a semiconductor light emitting device 10 of a second modification includes a first edge light emitting element 30A, a second edge light emitting element 30B, a third edge light emitting element 30C, and a fourth edge light emitting element 30D as a plurality of edge light emitting elements 30, and a first light receiving element 40A and a second light receiving element 40B as a plurality of light receiving elements 40. That is, unlike the first modification, the number of light receiving elements 40 is smaller than the number of edge light emitting elements 30. The first light receiving element 40A is a light receiving element corresponding to the first edge light emitting element 30A and the second edge light emitting element 30B, and the second light receiving element 40B is a light receiving element corresponding to the third edge light emitting element 30C and the fourth edge light emitting element 30D.

Further, the semiconductor light emitting device 10 of the second modification includes a plurality of first front surface electrodes 61SA to 61SD according to the number of edge light emitting elements 30. On the other hand, in the semiconductor light emitting device 10 of the second modification, the number of fourth front surface electrodes is smaller than the number of edge light emitting elements 30. In the example shown in FIG. 17, the semiconductor light emitting device 10 includes two fourth front surface electrodes 64SA and 64SB.

The first front surface electrodes 61SA to 61SD, the fourth front surface electrode 64SA, and the fourth front surface electrode 64SB are disposed at positions overlapping one another when viewed from the Y direction, for example. In the example shown in FIG. 17, the first front surface electrodes 61SA to 61SD are disposed between the fourth front surface electrode 64SA and the fourth front surface electrode 64SB in the Y direction. That is, the fourth front surface electrodes 64SA and 64SB are disposed in a distributed manner at both end portions in the Y direction, which is the arrangement direction of the first front surface electrodes 61SA to 61SD and the fourth front surface electrodes 64SA and 64SB. The fourth front surface electrode 64SA is disposed to be closer to the substrate side surface 26 than the first front surface electrodes 61SA to 61SD. The fourth front surface electrode 64SB is disposed to be closer to the substrate side surface 25 than the first front surface electrodes 61SA to 61SD.

On the other hand, the number of the second front surface electrode 62S and the number of the third front surface electrode 63S are the same as in each embodiment. In other words, the second front surface electrode 62S and the third front surface electrode 63S serve as common front surface electrodes for the first light receiving element 40A and the second light receiving element 40B. Both the second front surface electrode 62S and the third front surface electrode 63S extend along the Y direction.

The first edge light emitting element 30A is mounted on the first front surface electrode 61SA. The first light emitting electrode 34 of the first edge light emitting element 30A and the fourth front surface electrode 64SA are connected by a wire WA. Therefore, the second light emitting electrode 35 (see FIG. 3) of the first edge light emitting element 30A is electrically connected to the first front surface electrode 61SA, and the first light emitting electrode 34 of the first edge light emitting element 30A is electrically connected to the fourth front surface electrode 64SA.

The second edge light emitting element 30B is mounted on the first front surface electrode 61SB. The first light emitting electrode 34 of the second edge light emitting element 30B and the fourth front surface electrode 64SA are connected by a wire WB. Therefore, the second light emitting electrode 35 of the second edge light emitting element 30B is electrically connected to the first front surface electrode 61SB, and the first light emitting electrode 34 of the second edge light emitting element 30B is electrically connected to the fourth front surface electrode 64SA. As described above, the fourth front surface electrode 64SA becomes a common front surface electrode (anode electrode) for the first edge light emitting element 30A and the second edge light emitting element 30B.

The third edge light emitting element 30C is mounted on the first front surface electrode 61SC. The first light emitting electrode 34 of the third edge light emitting element 30C and the fourth front surface electrode 64SB are connected by a wire WC. Therefore, the second light emitting electrode 35 of the third edge light emitting element 30C is electrically connected to the first front surface electrode 61SC, and the first light emitting electrode 34 of the third edge light emitting element 30C is electrically connected to the fourth front surface electrode 64SB.

The fourth edge light emitting element 30D is mounted on the first front surface electrode 61SD. The first light emitting electrode 34 of the fourth edge light emitting element 30D and the fourth front surface electrode 64SB are connected by a wire WD. Therefore, the second light emitting electrode 35 of the fourth edge light emitting element 30D is electrically connected to the first front surface electrode 61SD, and the first light emitting electrode 34 of the fourth edge light emitting element 30D is electrically connected to the fourth front surface electrode 64SB. As describe above, the fourth front surface electrode 64SB becomes a common front surface electrode (anode electrode) for the third edge light emitting element 30C and the fourth edge light emitting element 30D.

The first light receiving element 40A is disposed at a position facing the first edge light emitting element 30A and the second edge light emitting element 30B in the Y direction. The second element front surface 41 of the first light receiving element 40A faces both the second light emitting surface 33B of the first edge light emitting element 30A and the second light emitting surface 33B of the second edge light emitting element 30B. The arrangement mode of the first light receiving element 40A, the first edge light emitting element 30A, and the second edge light emitting element 30B may be the same as in the first embodiment. However, in FIG. 17, according to the change in the number of edge light emitting elements 30 facing one light receiving element 40, for example, a ratio of a dimension in the Y direction and a dimension in the X direction of each light receiving element 40 is different from that in the first embodiment. As shown in FIG. 17, the first light receiving element 40A is disposed at a position overlapping the first edge light emitting element 30A and the second edge light emitting element 30B when viewed from the X direction. In one example, in a plan view, a dimension of the first light receiving element 40A in the Y direction is larger than a sum of a dimension of the first edge light emitting element 30A in the Y direction, a dimension of the second edge light emitting element 30B in the Y direction, and a distance between the first edge light emitting element 30A and the second edge light emitting element 30B in the Y direction.

Light receiving regions 49 of the first light receiving element 40A are provided according to the number of edge light emitting elements 30. That is, the first light receiving element 40A has two light receiving regions 49 facing the emission regions 36 of the first edge light emitting element 30A and the second edge light emitting element 30B, respectively. The arrangement mode of each light receiving region 49 of the first light receiving element 40A and each emission region 36 of the first edge light emitting element 30A and the second edge light emitting element 30B is, for example, the same as in the first embodiment.

The second light receiving element 40B is disposed at a position facing the third edge light emitting element 30C and the fourth edge light emitting element 30D in the Y direction. The second element front surface 41 of the second light receiving element 40B faces the second light emitting surfaces 33B of the third edge light emitting element 30C and the fourth edge light emitting element 30D. The arrangement mode of the second light receiving element 40B, the third edge light emitting element 30C, and the fourth edge light emitting element 30D may be the same as in the first embodiment. However, in FIG. 17, according to the change in the number of edge light emitting elements 30 facing one light receiving element 40, for example, the ratio of the dimension in the Y direction and the dimension in the X direction of each light receiving element 40 is different from that in the first embodiment. As shown in FIG. 17, the second light receiving element 40B is disposed at a position overlapping the third edge light emitting element 30C and the fourth edge light emitting element 30D when viewed from the X direction. In one example, in a plan view, a dimension of the second light receiving element 40B in the Y direction is larger than a sum of a dimension of the third edge light emitting element 30C in the Y direction, a dimension of the fourth edge light emitting element 30D in the Y direction, and a distance between the third edge light emitting element 30C and the fourth edge light emitting element 30D.

Light receiving regions 49 of the second light receiving element 40B are provided according to the number of edge light emitting elements 30. That is, the second light receiving element 40B has two light receiving regions 49 facing the emission regions 36 of the third edge light emitting element 30C and the fourth edge light emitting element 30D. The arrangement mode of each light receiving region 49 of the second light receiving element 40B and each emission region 36 of the third edge light emitting element 30C and the fourth edge light emitting element 30D is, for example, the same as in the first embodiment.

Each of the first light receiving element 40A and the second light receiving element 40B has two first light receiving electrodes 47A and one second light receiving electrode 47B. Although not shown, the first light receiving electrodes 47A of each of the first and second light receiving elements 40A and 40B are mounted on the second front surface electrode 62S, and the second light receiving electrode 47B of each of the first and second light receiving elements 40A and 40B is mounted on the third front surface electrode 63S. Thus, the first light receiving electrodes 47A of each of the first and second light receiving elements 40A and 40B are electrically connected to the second front surface electrode 62S, and the second light receiving electrode 47B of each of the first and second receiving elements 40A and 40B is electrically connected to the third front surface electrode 63S.

The semiconductor light emitting device 10 includes, for example, a seal 50 (not shown). Although not shown, the seal 50 seals each of the first to fourth edge light emitting elements 30A to 30D, the first light receiving element 40A, and the second light receiving element 40B. The configuration of the seal 50 can be arbitrarily changed, and for example, the semiconductor light emitting device 10 may include the seal 50 of the sixth embodiment. Further, the semiconductor light emitting device 10 may include a case 100 (see FIG. 13) instead of the seal 50.

### Third Modification

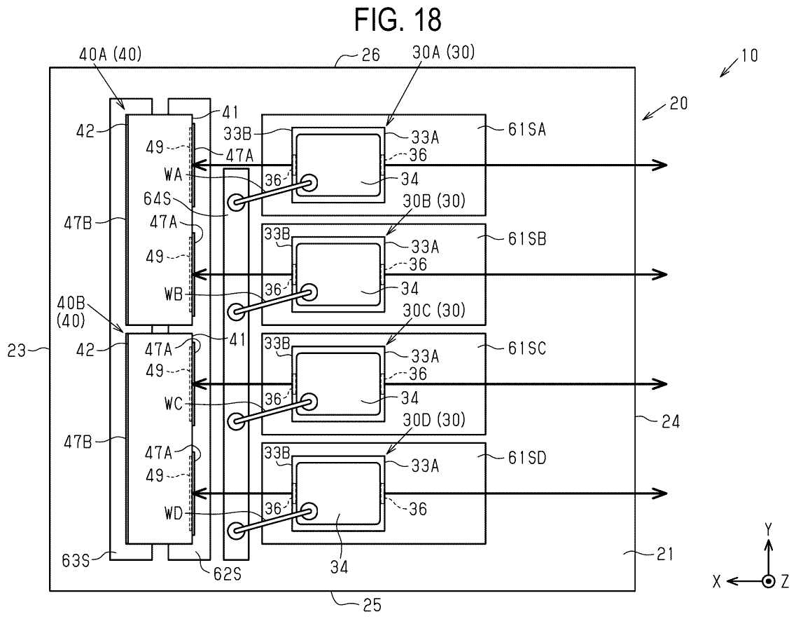

As shown in FIG. 18, a semiconductor light emitting device 10 of a third modification is different from the second modification in terms of the configuration and arrangement of the fourth front surface electrode 64S. Hereinafter, points different from the semiconductor light emitting device 10 of the second modification will be described in detail. Further, the same components as in the semiconductor light emitting device 10 of the second modification are denoted by the same reference numerals, and detailed explanation thereof will be omitted.

The semiconductor light emitting device 10 of the third modification includes one fourth front surface electrode 64S. The fourth front surface electrode 64S is disposed between the first front surface electrodes 61SA to 61SD and the second front surface electrode 62S in the X direction. The fourth front surface electrode 64S is formed in a band shape extending in the Y direction in a plan view. In the third modification, the fourth front surface electrode 64S becomes a common front surface electrode (anode electrode) for the first to fourth edge light emitting elements 30A to 30D.

On the other hand, the number of the second front surface electrode 62S and the number of the third front surface electrode 63S are the same as in each embodiment. That is, the second front surface electrode 62S and the third front surface electrode 63S serve as common front surface electrodes for the first light receiving element 40A and the second light receiving element 40B. Both the second front surface electrode 62S and the third front surface electrode 63S extend along the Y direction.

The first edge light emitting element 30A is mounted on the first front surface electrode 61S. The first light emitting electrode 34 of the first edge light emitting element 30A and the fourth front surface electrode 64S are connected by a wire WA. Therefore, the second light emitting electrode 35 (see FIG. 3) of the first edge light emitting element 30A is electrically connected to the first front surface electrode 61SA, and the first light emitting electrode 34 of the first edge light emitting element 30A is electrically connected to the fourth front surface electrode 64S.

In the example shown in FIG. 18, the wire WA is connected to be closer to the substrate side surface 25 than a center of the first light emitting electrode 34 of the first edge light emitting element 30A in the Y direction. The wire WA is formed between the second light emitting surface 33B of the first edge light emitting element 30A and the second light emitting surface 33B of the second edge light emitting element 30B in the Y direction in a plan view. The wire WA is connected to the fourth front surface electrode 64S via a side closer to the substrate side surface 25 than the emission region 36 of the first edge light emitting element 30A in the Y direction.

The second edge light emitting element 30B is mounted on the first front surface electrode 61SB. The first light emitting electrode 34 of the second edge light emitting element 30B and the fourth front surface electrode 64S are connected by a wire WB. Therefore, the second light emitting electrode 35 of the second edge light emitting element 30B is electrically connected to the first front surface electrode 61SB, and the first light emitting electrode 34 of the second edge light emitting element 30B is electrically connected to the fourth front surface electrode 64S.

In the example shown in FIG. 18, the wire WB is connected to be closer to the substrate side surface 25 than a center of the first light emitting electrode 34 of the second edge light emitting element 30B in the Y direction. The wire WB is formed between the second light emitting surface 33B of the second edge light emitting element 30B and the second light emitting surface 33B of the third edge light emitting element 30C in the Y direction in a plan view. The wire WB is connected to the fourth front surface electrode 64S via a side closer to the substrate side surface 25 than the emission region 36 of the second edge light emitting element 30B in the Y direction.

The third edge light emitting element 30C is mounted on the first front surface electrode 61SC. The first light emitting electrode 34 of the third edge light emitting element 30C and the fourth front surface electrode 64S are connected by a wire WC. Therefore, the second light emitting electrode 35 of the third edge light emitting element 30C is electrically connected to the first front surface electrode 61SC, and the first light emitting electrode 34 of the third edge light emitting element 30C is electrically connected to the fourth front surface electrode 64S.

In the example shown in FIG. 18, the wire WC is connected to be closer to the substrate side surface 25 than a center of the first light emitting electrode 34 of the third edge light emitting element 30C in the Y direction. The wire WC is formed between the second light emitting surface 33B of the third edge light emitting element 30C and the second light emitting surface 33B of the fourth edge light emitting element 30D in the Y direction in a plan view. The wire WC is connected to the fourth front surface electrode 64S via a side closer to the substrate side surface 25 than the emission region 36 of the third edge light emitting element 30C in the Y direction.

The fourth edge light emitting element 30D is mounted on the first front surface electrode 61SD. The first light emitting electrode 34 of the fourth edge light emitting element 30D and the fourth front surface electrode 64S are connected by a wire WD. Therefore, the second light emitting electrode 35 of the fourth edge light emitting element 30D is electrically connected to the first front surface electrode 61SD, and the first light emitting electrode 34 of the fourth edge light emitting element 30D is electrically connected to the fourth front surface electrode 64S.

In the example shown in FIG. 18, the wire WD is connected to be closer to the substrate side surface 25 than a center of the first light emitting electrode 34 of the fourth edge light emitting element 30D in the Y direction. The wire WD is connected to the fourth front surface electrode 64S via a side closer to the substrate side surface 25 than the emission region 36 of the fourth edge light emitting element 30D in the Y direction.

The wires WA to WD are formed so as not to overlap the emission region 36 when viewed from the X direction. Therefore, it is possible to suppress the wires WA to WD from blocking laser light emitted from the emission regions 36 of the second light emitting surfaces 33B of the first to fourth edge light emitting elements 30A to 30D.

Lengths of the wires WA to WD are equal to one another. Here, when a difference in length between two of the wires WA to WD is, for example, within 10% of a length of one wire, it can be said that the lengths of the two wires are equal to each other. Therefore, since paths for supplying a current from one fourth front surface electrode 64S to the first to fourth edge light emitting elements 30A to 30D are equal to one another, inductance components in the supply paths for the first to fourth edge light emitting elements 30A to 30D can be made equal to one another.

In addition, the number of fourth front surface electrodes 64S can be arbitrarily changed. In one example, the number of fourth front surface electrodes 64S may be two. In this case, one fourth front surface electrode 64S serves as a common front surface electrode for the first light emitting electrodes 34 of the edge light emitting elements 30A and 30B, and the other fourth front surface electrode 64S serves as a common front surface electrode for the first light emitting electrodes 34 of the edge light emitting elements 30C and 30D. In this case, the two fourth front surface electrodes 64S may be arranged, for example, at the same position in the X direction and spaced apart from each other in the Y direction. In another example, the number of fourth front surface electrodes 64S may be four. That is, the number of fourth front surface electrodes 64S may be the same as the number of first to fourth edge light emitting elements 30A to 30D. In this case, the four fourth front surface electrodes 64S and the first light emitting electrodes 34 of the first to fourth edge light emitting elements 30A to 30D are electrically connected individually by the wires WA to WD. The four fourth front surface electrodes 64S may be arranged, for example, at the same position in the X direction and spaced apart from one another in the Y direction.

In addition, the number of the light receiving elements 40 may be four according to the number of the edge light emitting elements 30.

### Fourth Modification

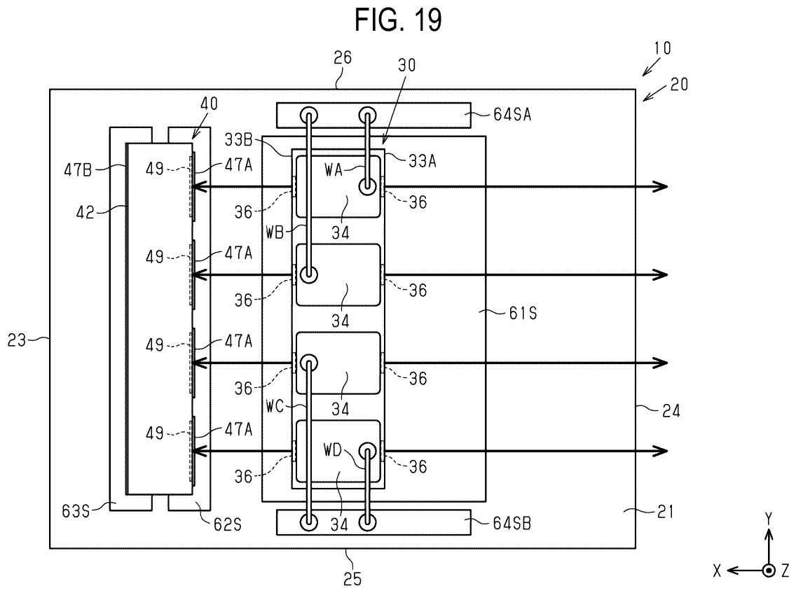

As shown in FIG. 19, a semiconductor light emitting device 10 of a fourth modification includes one edge light emitting element 30 including a plurality of emission regions 36 and one light receiving element 40 including a plurality of first light receiving electrodes 47A. Further, in one example, the light receiving element 40 includes the same number of light receiving regions 49 as the emission regions 36 of the edge light emitting element 30. In the example shown in FIG. 19, the edge light emitting element 30 has four emission regions 36, and the light receiving element 40 has four light receiving regions 49. In addition, in the example shown in FIG. 19, the light receiving element 40 has four first light receiving electrodes 47A.

The four emission regions 36 of the edge light emitting element 30 are arranged to be spaced apart from one another in the Y direction. Therefore, the edge light emitting element 30 is formed in a rectangular shape having the Y direction as a longitudinal direction and the X direction as a lateral direction in a plan view. The edge light emitting element 30 includes a plurality of first light emitting electrodes 34 and the number of first light emitting electrodes 34 corresponds to the number of emission regions 36. In the fourth modification, the edge light emitting element 30 includes four first light emitting electrodes 34. The four first light emitting electrodes 34 are arranged to be spaced apart from one another in the Y direction.

The four light receiving regions 49 of the light receiving element 40 are arranged to be spaced apart from one another in the Y direction. Therefore, the light receiving element 40 is formed in a rectangular shape having the Y direction as a longitudinal direction and the X direction as a lateral direction in a plan view. In one example, a dimension of the light receiving element 40 in the Y direction may be equal to or larger than a dimension of the edge light emitting element 30 in the Y direction.

As shown in FIG. 19, the semiconductor light emitting device 10 of the fourth modification includes two fourth front surface electrodes 64SA and 64SB. On the other hand, the numbers of first front surface electrodes 61S, second front surface electrodes 62S, and third front surface electrodes 63S are the same as in each embodiment. The first front surface electrode 61S is formed in a rectangular shape having the Y direction as a longitudinal direction and the X direction as a lateral direction according to a size of the edge light emitting element 30. Both the second front surface electrode 62S and the third front surface electrode 63S are formed in a band shape extending in the Y direction.

In one example, the first front surface electrode 61S and the fourth front surface electrodes 64SA and 64SB are disposed at positions overlapping one another when viewed from the Y direction, and the first front surface electrode 61S is disposed between the fourth front surface electrode 64SA and the fourth front surface electrode 64SB in the Y direction. Both the second front surface electrode 62S and the third front surface electrode 63S are formed in a band shape extending in the Y direction.

The edge light emitting element 30 is mounted on the first front surface electrode 61S. The four first light emitting electrodes 34 and the fourth front surface electrodes 64SA and 64SB are individually connected by wires WA to WD. More specifically, among the four first light emitting electrodes 34, two first light emitting electrodes 34, which are close to the fourth front surface electrode 64SA, and the fourth front surface electrode 64SA are individually connected by the wires WA and WB. The remaining two first light emitting electrodes 34, which are close to the fourth front surface electrode 64SB, and the fourth front surface electrode 64SB are individually connected by the wires WC and WD. Therefore, the second light emitting electrode 35 (see FIG. 3) of the edge light emitting element 30 is electrically connected to the first front surface electrode 61S, and the first light emitting electrodes 34 of the edge light emitting element 30 are electrically connected to the fourth front surface electrode 64SA and the fourth front surface electrode 64SB.

In addition, the arrangement mode of the edge light emitting element 30 and the light receiving element 40 may be the same as in the first embodiment. As shown in FIG. 19, the light receiving element 40 is disposed at a position overlapping the edge light emitting element 30 when viewed from the X direction.

The four first light receiving electrodes 47A of the light receiving element 40 are mounted on the second front surface electrode 62S, and the second light receiving electrode 47B of the light receiving element 40 is mounted on the third front surface electrode 63S. Thus, the four first light receiving electrodes 47A of the light receiving element 40 are electrically connected to the second front surface electrode 62S, and the second light receiving electrode 47B of the light receiving element 40 is electrically connected to the third front surface electrode 63S. The number of second light receiving electrodes 47B may be four according to the number of first light receiving electrodes 47A.

The semiconductor light emitting device 10 includes, for example, a seal 50 (not shown). Although not shown, the seal 50 seals each of the edge light emitting element 30 and the light receiving element 40. The configuration of the seal 50 can be arbitrarily changed, and for example, the semiconductor light emitting device 10 may include the seal 50 of the sixth embodiment. Further, the semiconductor light emitting device 10 may include a case 100 (see FIG. 13) instead of the seal 50.

### Fifth Modification

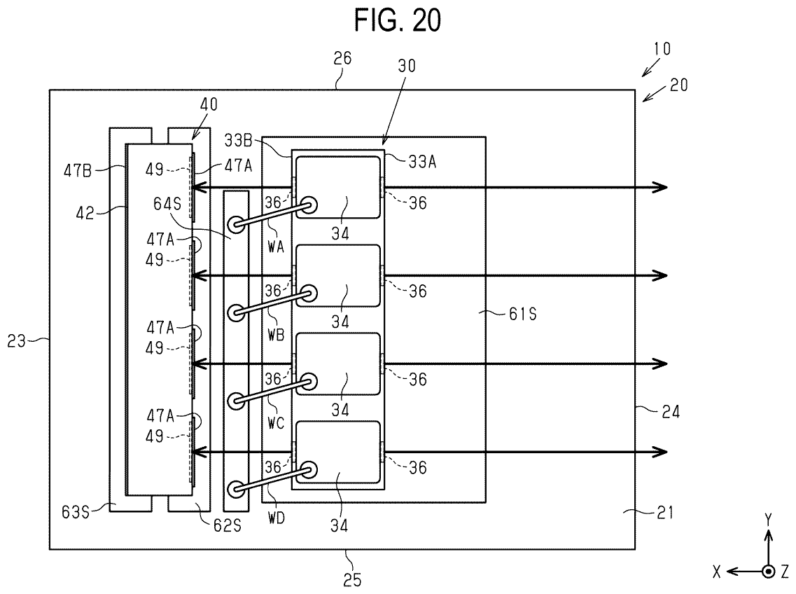

As shown in FIG. 20, a semiconductor light emitting device 10 of a fifth modification is different from the semiconductor light emitting device 10 of the fourth modification in terms of the configuration and arrangement of the fourth front surface electrode 64S. Hereinafter, points different from the semiconductor light emitting device 10 of the fourth modification will be described in detail. Further, the same components as in the semiconductor light emitting device 10 of the fourth modification are denoted by the same reference numerals, and detailed explanation thereof will be omitted.

The semiconductor light emitting device 10 of the fifth modification includes one fourth front surface electrode 64S. The fourth front surface electrode 64S is disposed between the first front surface electrode 61S and the second front surface electrode 62S in the X direction.

Further, similarly to the fourth modification, the edge light emitting element 30 has four emission regions 36, and the light receiving element 40 has four light receiving regions 49. The light receiving element 40 has four first light receiving electrodes 47A.

The four first light emitting electrodes 34 of the edge light emitting element 30 and one fourth front surface electrode 64S are individually connected by four wires WA to WD.

In the example shown in FIG. 20, the wires WA to WD are connected to be closer to the substrate side surface 25 than a center of the first light emitting electrode 34 of the edge light emitting element 30 in the Y direction. The wires WA to WC are formed between two emission regions 36 that are adjacent to each other in the Y direction in a plan view. The wires WA to WD are connected to the fourth front surface electrode 64S via a side closer to the substrate side surface 25 than each emission region 36 of the edge light emitting element 30 in the Y direction.

In the semiconductor light emitting device 10 of the fifth modification, similarly to the semiconductor light emitting device 10 of the third modification shown in FIG. 18, the wires WA to WD are formed so as not to overlap the emission regions 36 of the second light emitting surface 33B of the edge light emitting element 30. Therefore, it is possible to suppress the wires WA to WD from blocking laser light emitted from the emission regions 36 of the second light emitting surfaces 33B of the edge light emitting element 30. Further, in the semiconductor light emitting device 10 of the fifth modification, lengths of the wires WA to WD are equal to one another. Therefore, inductance components in the current supply paths for the plurality of first light emitting electrodes 34 of the edge light emitting element 30 can be made equal to one another.

### Sixth Modification

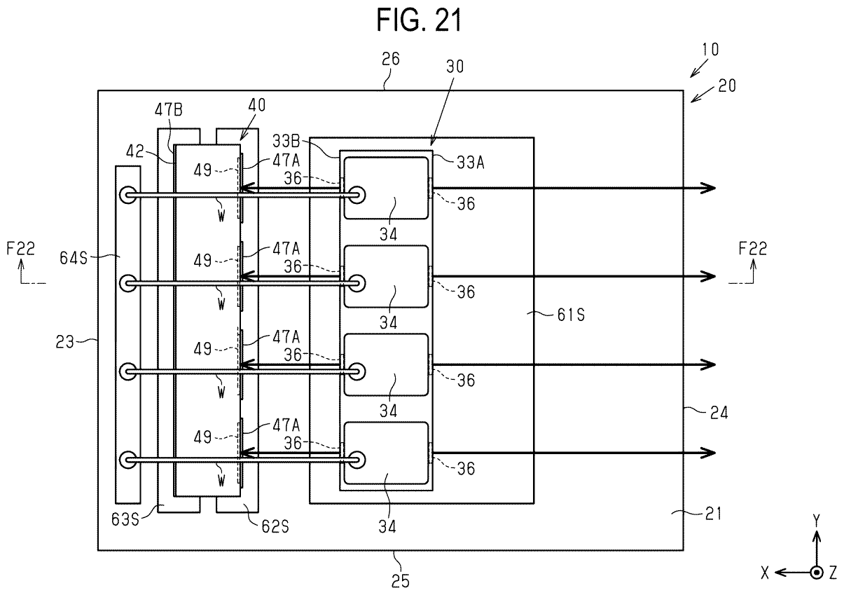

As shown in FIG. 21, a semiconductor light emitting device 10 of a sixth modification is different from the semiconductor light emitting device 10 of the fourth modification in terms of the configuration and arrangement of the fourth front surface electrode 64S. Hereinafter, points different from the semiconductor light emitting device 10 of the fourth modification will be described in detail. Further, the same components as in the semiconductor light emitting device 10 of the fourth modification are denoted by the same reference numerals, and detailed explanation thereof will be omitted.

The semiconductor light emitting device 10 of the sixth modification includes one fourth front surface electrode 64S. The fourth front surface electrode 64S is disposed on the opposite side of the edge light emitting element 30 with respect to the light receiving element 40. The fourth front surface electrode 64S is disposed to be closer to the substrate side surface 23 than the edge light emitting element 30 and the light receiving element 40. The fourth front surface electrode 64S is disposed to be spaced apart from the third front surface electrode 63S in a plan view. In one example, the fourth front surface electrode 64S is formed in a band shape extending in the Y direction.

The edge light emitting element 30 is mounted on the first front surface electrode 61S. The four first light emitting electrodes 34 of the edge light emitting element 30 and the fourth front surface electrode 64S are individually connected by four wires W.

The wires W electrically connecting each first light emitting electrode 34 of the edge light emitting element 30 and the fourth front surface electrode 64S are formed to extend from each first light emitting electrode 34 in the X direction. Further, lengths of the wires W are equal to one another. Here, when a difference in length between two wires W is within 10% of a length of one wire W, the lengths of the two wires W can be said to be equal to each other.

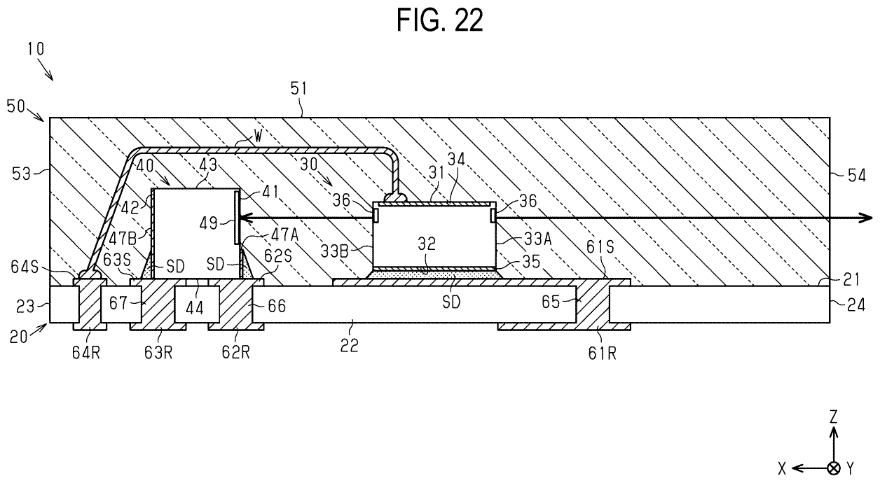

As shown in FIG. 22, the wire W electrically connecting the first light emitting electrode 34 of the edge light emitting element 30 and the fourth front surface electrode 64S is disposed so as to pass between the light receiving element 40 and the sealing front surface 51 in the Z direction. It can be said that the wire W is disposed so as to pass through an opposite side of the substrate 20 on which the light receiving element 40 is mounted with respect to the light receiving element 40.

In addition, when a case 100 (see FIG. 13) is used in the sixth modification, the wire W is disposed so as to pass between the light receiving element 40 and the case 100.

In addition, the number of edge light emitting elements 30 can be arbitrarily changed. In one example, the number of edge light emitting elements 30 may be four. In this case, each edge light emitting element 30 may be provided with one first light emitting electrode 34 and one emission region 36.

Further, the number of fourth front surface electrodes 64S can be arbitrarily changed. In one example, the number of fourth front surface electrodes 64S may be four. In this case, each fourth front surface electrode 64S becomes a front surface electrode connected to one of the four first light emitting electrodes 34 of the edge light emitting element 30. In this case, the four fourth front surface electrodes 64S are arranged, for example, at the same position in the X direction and spaced apart from one another in the Y direction.

In the first to eighth embodiments and respective modifications, the arrangement of the fourth front surface electrode 64S can be arbitrarily changed.

In the first to eighth embodiments and respective modifications, the position at which the wire W is connected to the first light emitting electrode 34 of the edge light emitting element 30 and the position at which the wire W is connected to the fourth front surface electrode 64S can be arbitrarily changed. In the first to eighth embodiments and the first to fifth modifications, it is only necessary that the wire W is formed at a position that does not overlap the emission region 36 when viewed from the X direction.

In the first to eighth embodiments, the positional relationship between the edge light emitting element 30 and the first front surface electrode 61S can be arbitrarily changed. In one example, in the first to sixth and eighth embodiments, the first front surface electrode 61S may be formed so as not to protrude from the second light emitting surface 33B of the edge light emitting element 30 toward the light receiving element 40 in a plan view.

In the first to eighth embodiments, the positional relationship between the light receiving element 40 and the second front surface electrode 62S can be arbitrarily changed. In one example, in the first to sixth and eighth embodiments, the second front surface electrode 62S may be formed so as not to protrude from the second element front surface 41 of the light receiving element 40 toward the edge light emitting element 30 in a plan view.

In the first to third and seventh embodiments, the seal 50 may be omitted.

In each embodiment, the semiconductor light emitting device 10 is not limited to a surface-mounted package structure. The semiconductor light emitting device 10 may be configured to mount the edge light emitting element 30 and the light receiving element 40 on a plurality of lead frames, instead of the substrate 20, the first to fourth front surface electrodes 61S to 64S, and the first to fourth back surface electrodes 61R to 64R. In this case, the semiconductor light emitting device 10 may include, for example, a seal 50 that seals the edge light emitting element 30 and the light receiving element 40 and partially seals each lead frame. A portion of each lead frame exposed from the seal 50 constitutes an external terminal.

One or more of the various examples described in the present disclosure can be combined unless technically contradictory.

The terms such as “first,” “second,” and “third” in the present disclosure are used merely to distinguish between objects and are not intended to rank the objects.

In the present disclosure, “at least one of A and B” should be understood to mean “only A, or only B, or both A and B.”

The term “on” as used in the present disclosure includes the meanings of “on” and “above” unless clearly stated otherwise in the context. Therefore, the expression “a first element is disposed on a second element” is intended that in some embodiments, the first element can be directly disposed on the second element in contact with the second element, while in other embodiments, the first element can be disposed above the second element without contacting the second element. That is, the term “on” does not exclude a structure in which other elements are formed between the first element and the second element.

The Z direction used in the present disclosure does not necessarily have to be the vertical direction, and it does not have to exactly coincide with the vertical direction. Therefore, various structures according to the present disclosure are not limited to “up” and “down” in the Z direction described herein being “up” and “down” in the vertical direction. For example, the X direction may be the vertical direction, or the Y direction may be the vertical direction.

### Supplementary Notes

The technical ideas that can be recognized from the present disclosure will be described below. In addition, for the purpose of aiding understanding and not for the purpose of limitation, constituent elements described in supplementary notes are labeled with the reference numerals of the corresponding constituent elements in the above-described embodiments. The reference numerals are provided as examples to aid understanding, and the constituent elements described in supplementary notes should not be limited to the constituent elements indicated by the reference numerals.

### Supplementary Note 1

A semiconductor light emitting device (10) including:
a substrate (20) having a substrate front surface (21);
a first front surface electrode (61S), a second front surface electrode (62S), and a third front surface electrode (63S) that are formed on the substrate front surface (21);
an edge light emitting element (30) that includes a first light emitting surface (33A) facing in a direction intersecting a thickness direction (Z direction) perpendicular to the substrate front surface (21) and a second light emitting surface (33B) facing in a direction opposite to the first light emitting surface (33A), and is electrically connected to the first front surface electrode (61S); and
a light receiving element (40) that includes a second element front surface (41) having a light receiving region (49) and is electrically connected to the second front surface electrode (62S) and the third front surface electrode (63S) with the second element front surface (41) facing the second light emitting surface (33B).

### Supplementary Note 2

The semiconductor light emitting device of Supplementary Note 1, wherein the light receiving element (40) further includes:
a second element back surface (42) opposite to the second element front surface (41);
a first light receiving electrode (47A) formed on the second element front surface (41); and a second light receiving electrode (47B) formed on the second element back surface (42),
wherein the first light receiving electrode (47A) is electrically connected to the second front surface electrode (62S), and
wherein the second light receiving electrode (47B) is electrically connected to the third front surface electrode (63S).

### Supplementary Note 3

The semiconductor light emitting device of Supplementary Note 1, wherein the light receiving element (40) further includes:
a second element back surface (42) opposite to the second element front surface (41); and
a first light receiving electrode (47A) and a second light receiving electrode (47B) that are formed to be spaced apart from each other on the second element back surface (42),
wherein the first light receiving electrode (47A) is electrically connected to the second front surface electrode (62S), and
wherein the second light receiving electrode (47B) is electrically connected to the third front surface electrode (63S).

### Supplementary Note 4

The semiconductor light emitting device of Supplementary Note 2 or 3, wherein the edge light emitting element (30) further includes:
a first element front surface (31) facing a same side as the substrate front surface (21);
a first element back surface (32) facing opposite to the first element front surface (31);
a first light emitting electrode (34) formed on the first element front surface (31); and
a second light emitting electrode (35) formed on the first element back surface (32),
wherein the second light emitting electrode (35) of the edge light emitting element (30) is electrically connected to the first front surface electrode (61S).

### Supplementary Note 5

The semiconductor light emitting device of Supplementary Note 4, further including a sub-mount substrate (90) that is interposed between the first front surface electrode (61S) and the edge light emitting element (30) in the thickness direction (Z direction) and is in contact with the first front surface electrode (61S) and the second light emitting electrode (35).

### Supplementary Note 6

The semiconductor light emitting device of Supplementary Note 5, wherein the sub-mount substrate (90) is made of a conductive material.

### Supplementary Note 7

The semiconductor light emitting device of Supplementary Note 5, wherein the sub-mount substrate (90) is made of an insulating material and includes a through-wiring that penetrates the sub-mount substrate (90) in the thickness direction (Z direction).

### Supplementary Note 8

The semiconductor light emitting device of any one of Supplementary Notes 1 to 7, wherein the second light emitting surface (33B) includes an emission region (36), and wherein the light receiving region (49) faces the emission region (36).

### Supplementary Note 9

The semiconductor light emitting device (10) of Supplementary Note 8, wherein an area of the light receiving region (49) is larger than an area of the emission region (36).

### Supplementary Note 10

The semiconductor light emitting device of Supplementary Note 9, wherein a center of the light receiving region (49) faces the emission region (36).

### Supplementary Note 11

The semiconductor light emitting device of Supplementary Note 9 or 10, wherein a size of the light receiving region (49) in the thickness direction (Z direction) is larger than a size of the second light emitting surface (33B) in the thickness direction (Z direction).

### Supplementary Note 12

The semiconductor light emitting device of any one of Supplementary Notes 1 to 11, further including a seal (50) that seals at least a portion of the edge light emitting element (30) and the light receiving element (40).

### Supplementary Note 13

The semiconductor light emitting device of Supplementary Note 12, wherein the seal (50) exposes the first light emitting surface (33A) of the edge light emitting element (30).

### Supplementary Note 14

The semiconductor light emitting device of Supplementary Note 12 or 13, wherein the seal (50) is made of a material that blocks visible light, and
wherein the edge light emitting element (30) is configured to emit laser light having a wavelength different from the visible light.

### Supplementary Note 15

The semiconductor light emitting device of any one of Supplementary Notes 12 to 14, wherein the seal (50) has a sealing front surface (51) facing a same side as the substrate front surface (21), and
wherein a light shielding layer (120) is provided on the sealing front surface (51) and between the second light emitting surface (33B) and the second element front surface (41) when viewed from the thickness direction (Z direction).

### Supplementary Note 16

The semiconductor light emitting device of any one of Supplementary Notes 12 to 15, further including a plurality of diffusers (72) that are provided in the seal (50) and diffuse laser light emitted by the edge light emitting element (30).

### Supplementary Note 17

The semiconductor light emitting device of any one of Supplementary Notes 1 to 16, wherein the edge light emitting element (30) is configured such that an output of laser light emitted from the second light emitting surface (33B) is smaller than an output of laser light emitted from the first light emitting surface (33A).

### Supplementary Note 18

The semiconductor light emitting device of any one of Supplementary Notes 1 to 17, wherein the substrate (20) has a substrate back surface (22) facing opposite to the substrate front surface (21) in the thickness direction (Z direction), and
wherein the semiconductor light emitting device further includes a back surface electrode (61R to 64R) formed on the substrate back surface (22).

### Supplementary Note 19

The semiconductor light emitting device of Supplementary Note 4, wherein the first front surface electrode (61S) includes a first protrusion (131) that protrudes from the second light emitting surface (33B) toward the light receiving element (40) when viewed from the thickness direction (Z direction),
wherein the second front surface electrode (62S) includes a second protrusion (132) that protrudes from the second element front surface (41) toward the edge light emitting element (30) when viewed from the thickness direction (Z direction), and
wherein the semiconductor light emitting device further includes an antireflection layer (140) that covers both the first protrusion (131) and the second protrusion (132).

### Supplementary Note 20

The semiconductor light emitting device of Supplementary Note 19, wherein a first conductive bonding material (SD1) that bonds the second light emitting electrode (35) and the first front surface electrode (61S) is provided in the first protrusion (131),
wherein a second conductive bonding material (SD2) that bonds the first light receiving electrode (47A) and the second front surface electrode (62S) is provided in the second protrusion (132), and
wherein the antireflection layer (140) covers both the first conductive bonding material (SD1) and the second conductive bonding material (SD2).

### Supplementary Note 21

The semiconductor light emitting device of Supplementary Note 4, further including:
a fourth front surface electrode (64S) formed on the substrate front surface (21); and
a wire (W) that connects the first light emitting electrode (34) and the fourth front surface electrode (64S),
wherein the wire (W) is located at a position different from an emission region (36) of the first light emitting surface (33A) and the second light emitting surface (33B) when viewed from an arrangement direction of the first light emitting surface (33A) and the second light emitting surface (33B).

### Supplementary Note 22

The semiconductor light emitting device of any one of Supplementary Notes 1 to 11, further including a case (100) that is provided on the substrate front surface (21) and accommodates the edge light emitting element (30) and the light receiving element (40).

### Supplementary Note 23

The semiconductor light emitting device of Supplementary Note 22, wherein the case (100) is made of a material that blocks visible light, and
wherein the edge light emitting element (30) is configured to emit laser light having a wavelength different from the visible light.

### Supplementary Note 24

The semiconductor light emitting device of Supplementary Note 22 or 23, wherein the case (100) is made of a light shielding material and includes an opening through which laser light emitted from the first light emitting surface (33A) passes.

### Supplementary Note 25

The semiconductor light emitting device of Supplementary Note 22 or 23, wherein the case (100) includes a side wall (102) disposed to face the first light emitting surface (33A),
wherein the side wall (102) is made of a material through which laser light emitted from the first light emitting surface (33A) can pass, and
wherein a light diffuser (104) that diffuses the laser light is formed in a region of the side wall (102) through which the laser light passes.

### Supplementary Note 26

The semiconductor light emitting device of any one of Supplementary Notes 5 to 7, wherein a thickness (LX1) of the light receiving element (40) is larger than a thickness (LZ1) of the sub-mount substrate (90).

### Supplementary Note 27

The semiconductor light emitting device of any one of Supplementary Notes 1 to 26, wherein a first element side surface (43) of the light receiving element (40) is located on an opposite side of the substrate (20) with respect to the first element front surface (31) of the edge light emitting element (30).

### Supplementary Note 28

The semiconductor light emitting device of Supplementary Note 1, wherein an arrangement direction of the first light emitting surface (33A) and the second light emitting surface (33B) is a first direction (X direction) and a direction orthogonal to the first direction (X direction) when viewed from the thickness direction (Z direction) is a second direction (Y direction),
wherein the edge light emitting element (30) includes a plurality of edge light emitting elements (30A to 30C) arranged to be spaced apart from each other in the second direction (Y direction), and
wherein the light receiving element includes a plurality of light receiving elements (40A to 40C) arranged to be spaced apart from each other in the second direction (Y direction).

### Supplementary Note 29

The semiconductor light emitting device of Supplementary Note 28, wherein light receiving regions (49) of the plurality of light receiving elements (40A to 40C) are disposed to individually face second light emitting surfaces (33B) of the plurality of edge light emitting elements (30A to 30C) in the first direction (X direction).

### Supplementary Note 30

The semiconductor light emitting device of Supplementary Note 29, wherein the number of light receiving elements (40A, 40B) is smaller than the number of edge light emitting elements (30A to 30D), and
wherein one light receiving element (40A/40B) is disposed to commonly face the second light emitting surfaces (33B) of the plurality of edge light emitting elements (30A, 30B/30C, 30D).

### Supplementary Note 31

The semiconductor light emitting device of any one of Supplementary Notes 8 to 11, wherein a dimension of the light receiving region (49) in the second direction (Y direction) is larger than a dimension of the light receiving region (49) in the thickness direction (Z direction).

### Supplementary Note 32

The semiconductor light emitting device of Supplementary Note 21, further including a plurality of edge light emitting elements (30A to 30D) arranged to be spaced apart from one another in a second direction (Y direction),
wherein the wire (W) includes a plurality of wires (WA to WD) that electrically connect the first light emitting electrodes (34) of the plurality of edge light emitting elements (30A to 30D) and the fourth front surface electrode (64S), and
wherein the fourth front surface electrode (64S) is disposed between the plurality of edge light emitting elements (30A to 30D) and the light receiving elements (40A, 40B).

### Supplementary Note 33

The semiconductor light emitting device of Supplementary Note 32, wherein the plurality of wires (WA to WD) is disposed at positions that do not overlap the emission region (36) of each of the plurality of edge light emitting elements (30A to 30D) when viewed from the first direction (X direction).

### Supplementary Note 34

The semiconductor light emitting device of Supplementary Note 21, wherein the edge light emitting element (30) includes a plurality of first light emitting electrodes (34) disposed to be spaced apart from one another in the second direction (Y direction),
wherein the wire (W) includes a plurality of wires (WA to WD) that electrically connect the plurality of first light emitting electrodes (34) of the edge light emitting element (30) and the fourth front surface electrode (64S), and
wherein the fourth front surface electrode (64S) is disposed on an opposite side of the edge light emitting element (30) with respect to the light receiving element (40).

### Supplementary Note 35

The semiconductor light emitting device of Supplementary Note 34, wherein the plurality of wires (WA to WD) is disposed to pass through an opposite side of the substrate (20) with respect to the light receiving element (40).

The above description is merely an example. Those skilled in the art will appreciate that more possible combinations and substitutions are possible beyond the constituent elements and methods (manufacturing processes) listed for the purpose of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor light emitting device comprising:
a substrate having a substrate front surface;
a first front surface electrode, a second front surface electrode, and a third front surface electrode that are formed on the substrate front surface;
an edge light emitting element that includes a first light emitting surface facing in a direction intersecting a thickness direction perpendicular to the substrate front surface and a second light emitting surface facing in a direction opposite to the first light emitting surface, and is electrically connected to the first front surface electrode; and
a light receiving element that includes a second element front surface having a light receiving region and is electrically connected to the second front surface electrode and the third front surface electrode with the second element front surface facing the second light emitting surface.

2. The semiconductor light emitting device of claim 1, wherein the light receiving element further includes:
a second element back surface opposite to the second element front surface;
a first light receiving electrode formed on the second element front surface; and
a second light receiving electrode formed on the second element back surface,
wherein the first light receiving electrode is electrically connected to the second front surface electrode, and
wherein the second light receiving electrode is electrically connected to the third front surface electrode.

3. The semiconductor light emitting device of claim 1, wherein the light receiving element further includes:
a second element back surface opposite to the second element front surface; and
a first light receiving electrode and a second light receiving electrode that are formed to be spaced apart from each other on the second element back surface,
wherein the first light receiving electrode is electrically connected to the second front surface electrode, and
wherein the second light receiving electrode is electrically connected to the third front surface electrode.

4. The semiconductor light emitting device of claim 2, wherein the edge light emitting element further includes:
a first element front surface facing a same side as the substrate front surface;
a first element back surface facing opposite to the first element front surface;
a first light emitting electrode formed on the first element front surface; and
a second light emitting electrode formed on the first element back surface,
wherein the second light emitting electrode of the edge light emitting element is electrically connected to the first front surface electrode.

5. The semiconductor light emitting device of claim 4, further comprising a sub-mount substrate that is interposed between the first front surface electrode and the edge light emitting element in the thickness direction and is in contact with the first front surface electrode and the second light emitting electrode.

6. The semiconductor light emitting device of claim 5, wherein the sub-mount substrate is made of a conductive material.

7. The semiconductor light emitting device of claim 5, wherein the sub-mount substrate is made of an insulating material and includes a through-wiring that penetrates the sub-mount substrate in the thickness direction.

8. The semiconductor light emitting device of claim 1, wherein the second light emitting surface includes an emission region, and
wherein the light receiving region faces the emission region.

9. The semiconductor light emitting device of claim 8, wherein an area of the light receiving region is larger than an area of the emission region.

10. The semiconductor light emitting device of claim 9, wherein a center of the light receiving region faces the emission region.

11. The semiconductor light emitting device of claim 9, wherein a size of the light receiving region in the thickness direction is larger than a size of the second light emitting surface in the thickness direction.

12. The semiconductor light emitting device of claim 1, further comprising a seal that seals at least a portion of the edge light emitting element and the light receiving element.

13. The semiconductor light emitting device of claim 12, wherein the seal exposes the first light emitting surface of the edge light emitting element.

14. The semiconductor light emitting device of claim 12, wherein the seal is made of a material that blocks visible light, and
wherein the edge light emitting element is configured to emit laser light having a wavelength different from the visible light.

15. The semiconductor light emitting device of claim 12, wherein the seal has a sealing front surface facing a same side as the substrate front surface, and
wherein a light shielding layer is provided on the sealing front surface and between the second light emitting surface and the second element front surface when viewed from the thickness direction.

16. The semiconductor light emitting device of claim 12, further comprising a plurality of diffusers that are provided in the seal and diffuse laser light emitted by the edge light emitting element.

17. The semiconductor light emitting device of claim 1, wherein the edge light emitting element is configured such that an output of laser light emitted from the second light emitting surface is smaller than an output of laser light emitted from the first light emitting surface.

18. The semiconductor light emitting device of claim 1, wherein the substrate has a substrate back surface facing opposite to the substrate front surface in the thickness direction, and
wherein the semiconductor light emitting device further comprises a back surface electrode formed on the substrate back surface.

19. The semiconductor light emitting device of claim 4, wherein the first front surface electrode includes a first protrusion that protrudes from the second light emitting surface toward the light receiving element when viewed from the thickness direction,
wherein the second front surface electrode includes a second protrusion that protrudes from the second element front surface toward the edge light emitting element when viewed from the thickness direction, and
wherein the semiconductor light emitting device further comprises an antireflection layer that covers both the first protrusion and the second protrusion.

20. The semiconductor light emitting device of claim 19, wherein a first conductive bonding material that bonds the second light emitting electrode and the first front surface electrode is provided in the first protrusion,
wherein a second conductive bonding material that bonds the first light receiving electrode and the second front surface electrode is provided in the second protrusion, and
wherein the antireflection layer covers both the first conductive bonding material and the second conductive bonding material.
